(19) United States
(12) Patent Application Publication
(10) Pub. No.: US 2026/0362666 A1
(43) Pub. Date: Nov. 12, 2026

(54) TWO-PORT MEMORY CELL

(71) Applicant: Taiwan Semiconductor Manufacturing Company, Ltd., Hsinchu (TW)

(72) Inventor: Jhon Jhy LIAW, Hsinchu County (TW)

(21) Appl. No.: 19/204,231

(22) Filed: May 9, 2025

(51) Int. Cl. H10B 10/00; G11C 11/412; G11C 11/419; H10D 89/10

(52) U.S. Cl. CPC H10B 10/12; G11C 11/412; G11C 11/419; H10D 89/10

(57) ABSTRACT

The memory device according to the present disclosure includes a first pass-gate device, a first pull-down device, a second pull-down device, and a second pass-gate device disposed over a first active region extending along a first direction, and a read pass-gate device, a first pull-up device, a second pull-up device, and a dummy device disposed over a second active region extending along the first direction. A first gate structure of a first pass-gate device is isolated from a second gate structure of the read pass-gate device. The first pull-down device and the first pull-up device share a third gate structure. The second pull-down device and the second pull-up device share a fourth gate structure. A fifth gate structure of the second pass-gate device is isolated from a sixth gate structure of the dummy device. The first active region is longer than the second active region along the first direction.

### BACKGROUND

The semiconductor industry has experienced rapid growth. Technological advances in semiconductor materials and design have produced generations of semiconductor devices where each generation has smaller and more complex circuits than the previous generation. In the course of integrated circuit (IC) evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, these advances have also increased the complexity of processing and manufacturing semiconductor devices.

In deep sub-micron integrated circuit technology, an embedded static random access memory (SRAM) device has become a popular storage unit of high speed communication, image processing and system-on-chip (SOC) products. As back-end-of-line (BEOL) routing structures are getting ever more complex, metal thicknesses and line widths in low-level metallization layers continue to shrink in dimensions. This presents challenges to SRAM cell speed and stable minimum operating voltage (Vmin).

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic circuit diagram of static random access memory (SRAM) cells, according to various aspects of the present disclosure.

FIG. 2 is a schematic front-end-of-line (FEOL) layout of the SRAM cells in FIG. 1, according to various aspects of the present disclosure.

FIG. 3 is a schematic layout of a first frontside metallization layer over the FEOL layout in FIG. 2, according to various aspects of the present disclosure.

FIG. 4 is a schematic layout of a first backside metallization layer below the FEOL layout in FIG. 2, according to various aspects of the present disclosure.

FIG. 5 is a schematic layout of a second frontside metallization layer and a third frontside metallization layer over the first frontside metallization layer in FIG. 3, according to a first embodiment of the present disclosure.

FIG. 6 is a schematic layout of first two backside metallization layers below the FEOL layout in FIG. 2, according to a first embodiment of the present disclosure.

FIG. 7 is a schematic layout of a second frontside metallization layer, a third frontside metallization layer, and a fourth frontside metallization layer over the first frontside metallization layer in FIG. 3, according to a second embodiment of the present disclosure.

FIG. 8 is a schematic layout of first two backside metallization layers below the FEOL layout in FIG. 2, according to a second embodiment of the present disclosure.

FIG. 9 is a schematic layout of a second frontside metallization layer, a third frontside metallization layer, a fourth frontside metallization layer, and a fifth frontside metallization layer over the first frontside metallization layer in FIG. 3, according to a third embodiment of the present disclosure.

FIG. 10 is a schematic layout of first two backside metallization layers below the FEOL layout in FIG. 2, according to a third embodiment of the present disclosure.

FIG. 11 is a schematic layout of a second frontside metallization layer and a third frontside metallization layer over the first frontside metallization layer in FIG. 3, according to a fourth embodiment of the present disclosure.

FIG. 12 is a schematic layout of first two backside metallization layers below the FEOL layout in FIG. 2, according to a fourth embodiment of the present disclosure.

FIG. 13 is a schematic layout of a second frontside metallization layer and a third frontside metallization layer over the first frontside metallization layer in FIG. 3, according to a fifth embodiment of the present disclosure.

FIG. 14 is a schematic layout of first two backside metallization layers below the FEOL layout in FIG. 2, according to a fifth embodiment of the present disclosure.

FIG. 15 is a schematic layout of a first frontside metallization layer over an alternative FEOL layout, according to various aspects of the present disclosure.

FIG. 16 is a schematic layout of a first backside metallization layer below an alternative FEOL layout, according to various aspects of the present disclosure.

FIG. 17 is a schematic layout of a second frontside metallization layer and a third frontside metallization layer over the first frontside metallization layer in FIG. 15, according to a sixth embodiment of the present disclosure.

FIG. 18 is a schematic layout of first two backside metallization layers below the alternative FEOL layout in FIG. 15, according to a sixth embodiment of the present disclosure.

FIG. 19 is a schematic layout of a second frontside metallization layer, a third frontside metallization layer, and a fourth frontside metallization layer over the first frontside metallization layer in FIG. 15, according to a seventh embodiment of the present disclosure.

FIG. 20 is a schematic layout of first two backside metallization layers below the alternative FEOL layout in FIG. 15, according to a seventh embodiment of the present disclosure.

FIG. 21 is a schematic layout of a second frontside metallization layer, a third frontside metallization layer, a fourth frontside metallization layer, and a fifth frontside metallization layer over the first frontside metallization layer in FIG. 15, according to an eighth embodiment of the present disclosure.

FIG. 22 is a schematic layout of first two backside metallization layers below the alternative FEOL layout in FIG. 15, according to a third embodiment of the present disclosure.

FIG. 23 is a schematic cross-sectional view along line A-A′ in FIGS. 3 and 4, according to various aspects of the present disclosure.

FIG. 24 is a schematic cross-sectional view along line B-B′ in FIGS. 3 and 4, according to various aspects of the present disclosure.

FIG. 25 is a schematic cross-sectional view along line C-C′ in FIGS. 3 and 4, according to various aspects of the present disclosure.

FIG. 26 is a schematic cross-sectional view along line D-D′ in FIGS. 3 and 4, according to various aspects of the present disclosure.

FIG. 27 is a schematic cross-sectional view along line E-E′ in FIGS. 3 and 4, according to various aspects of the present disclosure.

FIG. 28 is a schematic cross-sectional view along line F-F′ in FIGS. 3 and 4, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Static Random Access Memory (SRAM) is commonly used in integrated circuits as it is featured with the ability to hold data without the need to refresh. To achieve bit-line capacitance reduction, a common wisdom is to place bit lines in low-level metallization layers over an SRAM cell. With other routing needs competing with bid lines, metal line pitches and widths in the low-level metallization layers may be pushed to the limit. The smaller metal line widths may result in high resistance, impacting the SRAM cell speed and minimum operating voltage stability. When the SRAM cell has a more complicated structure, the routing structure may become more complicated as well. Improvement of the back-end-of-line (BEOL) routing structures for SRAM cells is needed.

The present disclosure provides a two-port SRAM cell and a routing structure for the two-port SRAM cell. A two-port SRAM cell according to the present disclosure includes a first pass-gate device, a first pull-down device, a second pull-down device, a second pass-gate device, a read pass-gate device, a first pull-up device, a second pull-up device, and a dummy device. The first pass-gate device, the first pull-down device, the second pull-down device, and the second pass-gate device are disposed over a first active region extending along a first direction. The read pass-gate device, the first pull-up device, the second pull-up device, and the dummy device are disposed over a second active region extending along the first direction. A first gate structure of a first pass-gate device is isolated from a second gate structure of the read pass-gate device. The first pull-down device and the first pull-up device share a third gate structure. The second pull-down device and the second pull-up device share a fourth gate structure. A fifth gate structure of the second pass-gate device is isolated from a sixth gate structure of the dummy device. The routing for the two-port SRAM cell is achieved by at least one backside metallization layer and multiple frontside metallization layers. A read bit line extends along the first direction in a first frontside metallization layer over the two-port SRAM cell. A first bit line and a second bit line extend along the first direction in a second frontside metallization layer or a third frontside metallization layer over the two-port SRAM cell. Four word lines extend in two of the second frontside metallization layer, the third frontside metallization layer, the fourth frontside metallization layer, and/or the fifth frontside metallization layer that does not include the read bit line, the first bit line, and the second bit line.

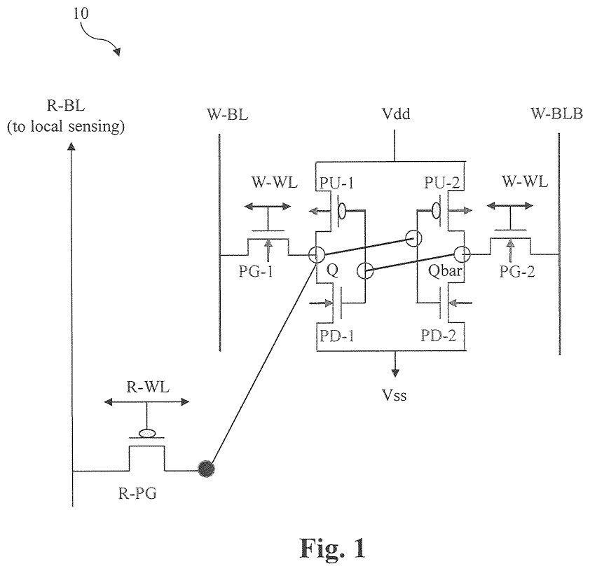

FIG. 1 is a schematic circuit diagram of a two-port static random access memory (2P-SRAM) cell 10. The 2P SRAM cell 10 may be implemented using planar field effect transistors (FETs) or multi-gate transistors. A planar FET includes a gate structure that may induce a planar channel region along one surface of its active region, hence its name. A multi-gate transistor includes a gate structure that is in contact with at least two surfaces of its active region. Examples of multi-gate transistors include fin-type FETs (FinFETs) and gate-all-around (GAA) transistors. A FinFET includes a fin-shaped active region arising from a substrate and a gate structure disposed over a top surface and sidewalls of the fin-shaped active region. A GAA transistor includes at least one channel member extending between two source/drain features and a gate structure that wraps completely around the at least one channel member. Because its gate structure wraps around the channel member, a GAA transistor may also be referred to as a multi-bridge channel (MBC) transistor or a surrounding gate transistor (SGT). Depending on the shapes and orientation, a channel member in a GAA transistor may be referred to as a nanosheet, a semiconductor wire, a nanowire, a nanostructure, a nano-post, a nano-beam, or a nano-bridge. In some instances, a GAA transistor may be referred to by the shape of the channel member. For example, a GAA transistor having one or more nanosheet channel member may also be referred to as a nanosheet transistor.

In some embodiments represented in FIG. 1, the 2P SRAM cell 10 includes seven transistors (7T): a first pass-gate device (PG-1), a first pull-down device (PU-1), a second pull-down device (PD-1), a second pass-gate device (PG-2), a read pass-gate device (R-PG), a first pull-up device (PU-1), and a second pull-up device (PU-2). In the depicted embodiments, the first pass-gate device (PG-1), the first pull-down device (PU-1), the second pull-down device (PD-1), and the second pass-gate device (PG-2) are each implemented as an n-type multi-gate transistor and the read pass-gate device (R-PG), the first pull-up device (PU-1), and the second pull-up device (PU-2) are each implemented as a p-type multi-gate transistor. For this reason, these devices may also be referred to as transistors. In the schematic circuit diagram in FIG. 1, the first pull-up device (PU-1), and the first pull-down device (PD-1) form a first inverter and the second pull-up device (PU-2), and the second pull-down device (PD-2) form a second inverter. The two inverters are cross-coupled to each other. Power is supplied to each of the inverters. Sources of the first pull-up device (PU-1) and the second pull-up device (PU-2) are coupled to a power supply Vdd, while sources of the first pull-down device (PD-1) and the second pull-down device (PD-2) are coupled to a reference voltage Vss. In some instances, the reference voltage Vss may be a ground voltage. A bit of data is stored in the 2P SRAM cell 10 at the node Q. The data stored at the node Q can be read by circuitry (e.g., a sense amplifier) via a read bit line R-BL, which is enabled through a read pass-gate device (R-PG) by a read word line R-WL. Access (e.g., write operation) to the node Q is controlled by the first pass-gate device (PG-1). The node Qbar stores the complement to value at node Q. That is, when node Q is “high,” node Qbar is “low.” Access (e.g., write operation) to node Qbar is controlled by the second pass-gate device (PG-2). Gates of the first pass-gate device (PG-1) and the second pass-gate device (PG-2) are controlled by a write word line W-WL. A first source/drain (S/D) of the first pass-gate device (PG-1) is coupled to a write bit line W-BL, and a second source/drain (S/D) of the first pass-gate device (PG-1) is coupled to the drains of the first pull-up device (PU-1) and the first pull-down device (PD-1) at the node Q. Similarly, a first S/D of the second pass-gate device (PG-2) is coupled to a complementary write bit line W-BLB, and a second S/D of the second pass-gate device (PG-2) is coupled to drains of the second pull-up device (PU-2) and the second pull-down device (PD-2) at the node Qbar.

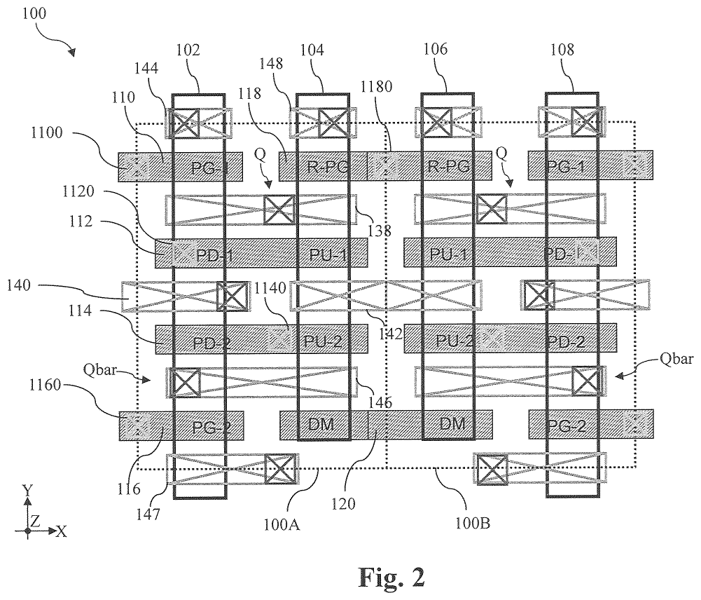

Reference is now made to FIG. 2. FIG. 2 illustrates a front-end-of-line (FEOL) layout of a dual cell 100 that includes a first cell 100A and a second cell 100B that are joined along a center line extending along the Y direction. It is noted that the illustration of the dual cell 100 is for the purposes of demonstrating the highly symmetric nature of the SRAM cells of the present disclosure and how two adjacent SRAM cells abut one another. In fact, as described further below, two gate structures extend cross the boundary between the first cell 100A and 100B and are shared by the two neighboring shells. Each of the first cell 100A and the second cell 100B is an implementation of the 2P SRAM cell 10 in FIG. 1. That is, each of the first cell 100A and the second cell 100B is a 2P SRAM cell with seven (7) transistors, including two pass-gate transistors, two pull-up transistors, two pull-down transistors, and a read pass-gate transistor. To maintain a uniform pattern density to prevent loading effect, each of the first cell 100A and the second cell 100B further includes a dummy device. Because the first cell 100A is a mirror image of the second cell 100B along the boundary of the two cells, the following description of the first cell 100A generally applies to the second cell 100B and counterparts of the features in the first cell 100A may be found in the second cell 100B.

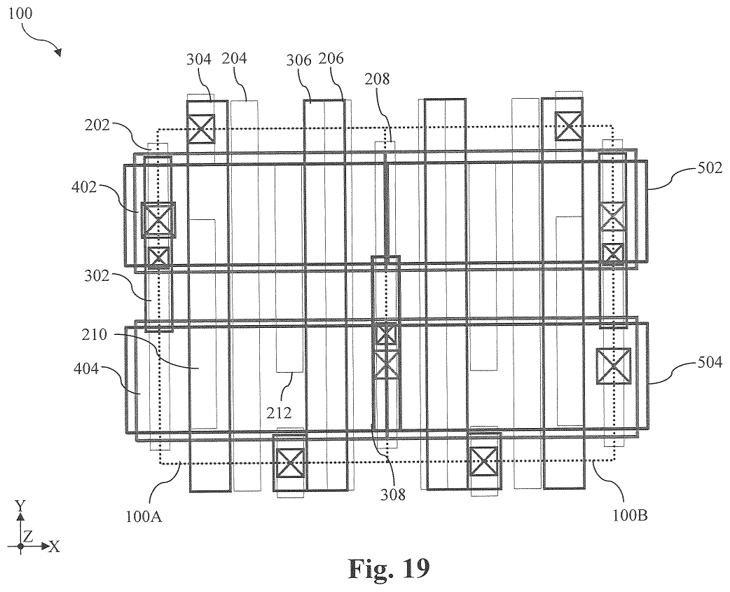

Referring to the first cell 100A shown in the left-hand-side of FIG. 2. The first cell 100A includes a first pass-gate transistor (PG-1), a second pass-gate transistor (PG-2), a first pull-down transistor (PD-1), and a second pull-down transistor (PD-2), a read pass-gate transistor (R-PG), a first pull-up transistor (PU-1), a second pull-up transistor (PU-2), and a dummy transistor (DM). Because the dual cell 100 includes backside interconnect features. The transistors in the first cell 100A are not disposed over any doped wells, buried insulator, or buried oxide structures. In the first cell 100A, the first pass-gate transistor (PG-1), the second pass-gate transistor (PG-2), the first pull-down transistor (PD-1), and the second pull-down transistor (PD-2) are disposed over or share a first active region 102. The read pass-gate transistor (R-PG), the first pull-up transistor (PU-1), the second pull-up transistor (PU-2), and the dummy transistor (DM) are disposed over or share a second active region 104. As used herein, an active region, such as the first active region 102 and the second active region 104, refers to a fin-like structure patterned from an epitaxial stack and a semiconductor substrate. As shown in the cross-sectional views in FIGS. 19-22, each of the active regions includes a base portion and channel members disposed over the base portion. The base portion, or base fin, is patterned from the semiconductor substrate and the channel members patterned from the epitaxial stack over the semiconductor substrate. In the source/drain regions of the transistors, portions of the active regions are recessed to form source/drain trenches. Source/drain features are then formed in the source/drain trenches. The formation of the channel members and the source/drain features does not negate the fact that these structures may be regarded as part of an active region.

In FIG. 2, the first active region 102 and the second active region 104 in the first cell 100A extend lengthwise along the Y direction. In some embodiments represented in FIG. 2, the second active region 104 is shorter than the first active region 102. The first active region 102 extends past the gate structure (i.e., the fourth gate structure 116) of the second pass-gate transistor (PG-2) to form a source/drain region of the second pass-gate transistor (PG-2). The second active region 104, albeit also extending along the Y direction, terminates at a boundary of the gate structure (i.e., the sixth gate structure 120) of the dummy transistor (DM). That is, a length of the first active region 102 along the Y direction is smaller than a length of the second active region 104 along the Y direction. This configuration is not trivial. If the second active region 104 also extends past the gate structure (i.e., the sixth gate structure 120) of the dummy transistor (DM), it may come in contact with source/drain contact coupled to the source/drain feature of the second pass-gate transistor (PG-2). The contact increases the risk of shorting the write bit line (W-BL) to the node Qbar. FIG. 2 also illustrates the counterparts of the first active region 102 and the second active region 104 in the second cell 100B. Being a mirror image of the first cell 100A, the second cell 100B also includes a first pass-gate transistor (PG-1), a second pass-gate transistor (PG-2), a first pull-down transistor (PD-1), and a second pull-down transistor (PD-2), a read pass-gate transistor (R-PG), a first pull-up transistor (PU-1), a second pull-up transistor (PU-2), and a dummy transistor (DM). The first pass-gate transistor (PG-1), the second pass-gate transistor (PG-2), the first pull-down transistor (PD-1), and the second pull-down transistor (PD-2) in the second cell 100B are disposed over or share a fourth active region 108. The read pass-gate transistor (R-PG), the first pull-up transistor (PU-1), the second pull-up transistor (PU-2), and the dummy transistor (DM) in the second cell 100B are disposed over or share a third active region 106. Along the Y direction, the second active region 104 and the third active region 106 have the same length, and the first active region 102 and the fourth active region 108 have the same length. The fourth active region 108 is longer than the third active region 106.

Referring still to FIG. 2, the gate structures of the first pass-gate transistor (PG-1), the second pass-gate transistor (PG-2), the first pull-down transistor (PD-1), and the second pull-down transistor (PD-2) are disposed over the first active region 102. The gate structures of the read pass-gate transistor (R-PG), the first pull-up transistor (PU-1), the second pull-up transistor (PU-2), and the dummy transistor (DM) extend lengthwise along the X direction that is perpendicular to the Y direction. As shown in FIG. 2, a first gate structure of the first pass-gate transistor (PG-1) and a fifth gate structure 118 of the read pass-gate transistor (R-PG) are isolated from one another. The first gate structure 110 and the fifth gate structure 118 extend lengthwise along the X direction and are aligned along the X direction. In some instances, the first gate structure 110 and the fifth gate structure 118 are formed as a single gate structure extending over the first active region 102 and the second active region 104 and then the single gate structure is segmented into the first gate structure 110 and the fifth gate structure 118 by a gate cut feature in a cut metal gate process. Because the second cell 100B is a mirror image of the first cell 100A, the fifth gate structure 118 is shared by the read pass-gate transistor (R-PG) in the second cell 100B. The first pull-down transistor (PD-1) and the first pull-up transistor (PU-1) are controlled by or share a second gate structure 112. The second gate structure 112 is not shared with the counterpart first pull-down transistor (PD-1) and the counterpart first pull-up transistor (PU-1) in the second cell 100B. The second pull-down transistor (PD-2) and the second pull-up transistor (PU-2) are controlled by or share a third gate structure 114. The third gate structure 114 is not shared with the counterpart second pull-down transistor (PD-2) and the counterpart second pull-up transistor (PU-2) in the second cell 100B. As shown in FIG. 2, a fourth gate structure 116 of the second pass-gate transistor (PG-2) and a sixth gate structure 120 of the dummy transistor (DM) are isolated from one another. The fourth gate structure 116 and the sixth gate structure 120 extend lengthwise along the X direction and are aligned along the X direction. In some instances, the fourth gate structure 116 and the sixth gate structure 120 are formed as a single gate structure extending over the first active region 102 and the second active region 104 and then the single gate structure is segmented into the fourth gate structure 116 and the sixth gate structure 120 by a gate cut feature in a cut metal gate process. Because the second cell 100B is a mirror image of the first cell 100A, the sixth gate structure 120 is shared by the dummy transistor (DM) in the second cell 100B. In some embodiments, the sixth gate structure 120 of the dummy transistors (DM) are electrically floating.

In the FEOL layout shown in FIG. 2, the first pass-gate transistor (PG-1), the second pass-gate transistor (PG-2), the first pull-down transistor (PD-1), and the second pull-down transistor (PD-2) are n-type multi-gate transistors having source/drain features including silicon (Si) and an n-type dopant, such as phosphorus (P) or arsenic (As). The read pass-gate transistor (R-PG), the first pull-up transistor (PU-1), the second pull-up transistor (PU-2), and the dummy transistor (DM) are p-type multi-gate transistors having source/drain features including silicon germanium (SiGe) and a p-type dopant, such as boron (B).

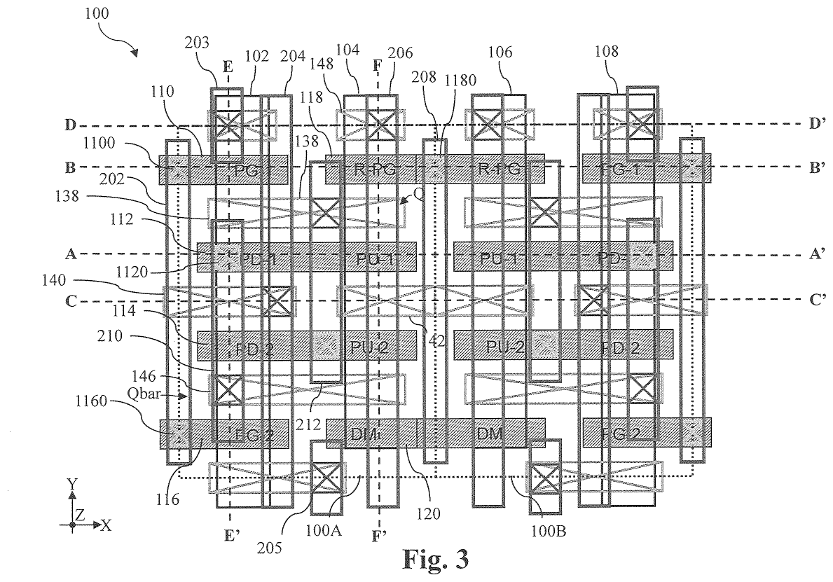

Referring still to FIG. 2, the drain of the first pull-down transistor (PD-1) and the drain of the first pull-up transistor (PU-1) are coupled to and share a first long source/drain contact 138 that spans over the first active region 102 and the second active region 104. This first long source/drain contact 138 is electrically coupled to the third gate structure 114 of the second pull-down transistor (PD-2) and the second pull-up transistor (PU-2) by a local interconnect to form the node Q. The source of the first pull-up transistor (PU-1) in the first cell 100A and the source of the first pull-up transistor (PU-1) in the second cell 100B are coupled to and shared a second long source/drain contact 142. The second long source/drain contact 142 crosses the boundary of the first cell 100A and the second cell 100B. The drain of the second pull-down transistor (PD-2) and the drain of the second pull-up transistor (PU-2) are coupled to and share a third long source/drain contact 146 that spans over the first active region 102 and the second active region 104. This third long source/drain contact 146 is electrically coupled to the second gate structure 112 of the first pull-down transistor (PD-1) and the first pull-up transistor (PU-1) by a local interconnect to form the node Qbar. For ease of illustrations, the local interconnects are shown in FIG. 3. The local interconnects are coupled to the gate structures and source/drain features by way of gate contact vias, such as a second gate contact via 1120 and a third gate contact via 1140, or source/drain vias. A first gate contact via 1100 is disposed over the source of the first gate structure 110 to couple with conductive features over the transistors. A contact via 1160 is disposed over the source of the fourth gate structure 116 to couple with conductive features over the transistors. Because the second cell 100B is a mirror image of the first cell 100A, detailed description of the source/drain contacts in the second cell 100B are omitted for brevity.

It is noted that FIG. 2 illustrates only front-end-of-line (FEOL) transistor structures as well as middle-end-of-line (MEOL) contact features that immediately interface the FEOL transistor structures. The routing of the dual cell 100 is implemented using metal features in back-end-of-line (BEOL) frontside metallization layers and BEOL backside metallization layers. The present disclosure illustrates routing structures that disposed with the first six (6) frontside metallization layers and first two (2) backside metallization layers. It should be understood that these examples and embodiments are for illustration purposes. Routing structures in more or less frontside or backside metallization layers may used or deployed to fulfill the functionality of the dual cell 100. For avoidance of doubt, the first frontside metallization layer (M1) refers to a lowest metallization layer over a FEOL transistor structures. The second (M2), third (M3), fourth (M4), fifth (M5), and sixth (M6) frontside metallization layers are metallization layers over and farther away from the FEOL transistor structures in their respective orders. The first backside metallization layer (BM1) refers to a highest metallization layer from a back side of the FEOL transistor structures. The second backside metallization layer (BM2) is a metallization layer below and farther away from the back surface of the FEOL transistor structures. Each of the frontside and backside metallization layers includes metal features in an intermetal dielectric (IMD) layer. The metal features may include vias, islands, pads, or metal lines. The metal features may include titanium nitride (TiN), tantalum nitride (TaN), copper (Cu), cobalt (Co), nickel (Ni), ruthenium (Ru), or tungsten (W). The IMD layer may include an oxide-based material or a low-k dielectric material. In some instances, the IMD layer includes silicon oxide.

Reference is now made to FIG. 3, which illustrates metal features in the first frontside metallization layer (M1) in additional to the FEOL and MEOL features shown in FIG. 2. In some embodiments represented in FIG. 3, the first frontside metallization layer (M1) includes a write word line (W-WL) landing pad 202, a write bit line (W-BL) island 203, a first local interconnect 210, a reference line 204, a second local interconnect 212, a write bit line bar (W-BLB) island 205, a read bit line (R-BL) line 206, and a read word line (R-WL) landing pad 208. The W-WL landing pad 202 extends lengthwise along the Y direction over the first gate structure 110 and the fourth gate structure 116. The W-WL landing pad 202 is electrically coupled to the first gate structure 110 by way of a first gate via 1100 and to the fourth gate structure 116 by way of a fourth gate via 1160. The W-WL landing pad 202 provides an intermediate conductive feature to enable a write word line in a higher frontside metallization layer(s). The write bit line (W-BL) island 203 is disposed over a source/drain feature of the first pass-gate transistor (PG-1). The write bit line (W-BL) island 203 is coupled to the source/drain feature by a source/drain contact via. The write bit line (W-BL) island 203 provides an intermediate conductive feature to enable a write bit line in a higher frontside metallization layer(s). The first local interconnect 210 extends lengthwise over the second gate structure 112, the third gate structure 114, and the third long source/drain contact 146 to couple the node Qbar to the second gate structure 112 that controls the first pull-down transistor (PD-1) and the first pull-up transistor (PU-1). The reference line 204 extends lengthwise along the Y direction over the first gate structure 110, the second gate structure 112, the third gate structure 114, and the fourth gate structure 116. The reference line 204 is electrically coupled to a source/drain contact 140 (that is coupled to the sources of the first pull-down transistor (PD-1) and the second pull-down transistor (PD-2)) by way of the source/drain contact via. The reference line 204 is coupled to the reference voltage Vss. The second local interconnect 212 extends lengthwise over the second gate structure 112, the third gate structure 114, and the first long source/drain contact 138 to couple the node Q to the third gate structure 114 that controls the second pull-down transistor (PD-2) and the second pull-up transistor (PU-2). The write bit line bar (W-BLB) island 205 is disposed over a source/drain feature of the second pass-gate transistor (PG-2). The write bit line bar (W-BLB) island 205 is coupled to the source/drain feature by a source/drain contact via. The write bit line bar (W-BLB) island 205 provides an intermediate conductive feature to enable a write complementary bit line in a higher frontside metallization layer(s). The read bit line (R-BL) line 206 extends lengthwise along the Y direction over the fifth gate structure 118, the second gate structure 112, the third gate structure 114, and the sixth gate structure 120. The read bit line (R-BL) line 206 is coupled to a source/drain of the read pass-gate transistor (R-PG) by way of a source/drain contact via. The R-WL landing pad 208 extends lengthwise along the Y direction over the fifth gate structure 118 and the sixth gate structure 120. The R-WL landing pad 208 is electrically coupled to the fifth gate structure 118 by way of a fifth gate via 1180. The R-WL landing pad 208 provides an intermediate conductive feature to enable a read word line in a higher frontside metallization layer(s). As shown in FIG. 3, the routing structures for the second cell 100B may mirror those for the first cell 100A. It is noted that the first cell 100A and the second cell 100B share the R-WL landing pad 208 that lands on a boundary of the first cell 100A and the second cell 100B.

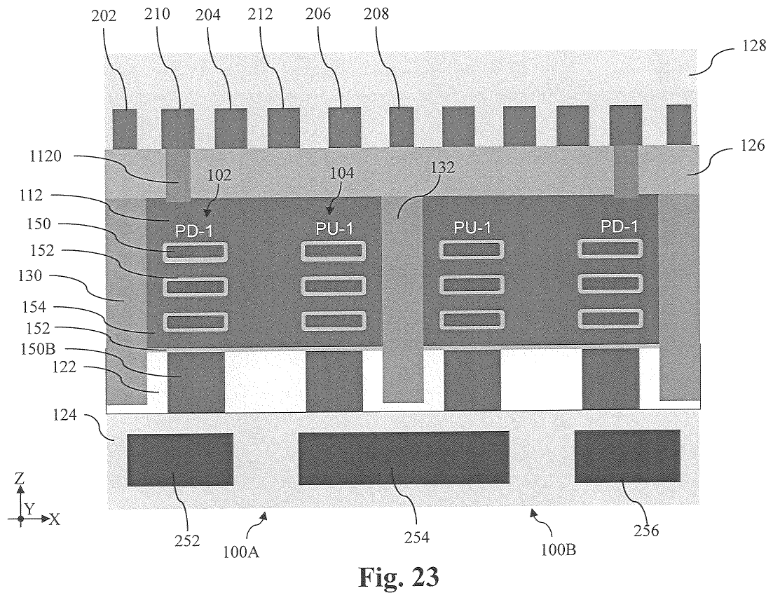

Fragmentary cross-sectional views of the dual cell 100 along lines A-A′, B-B′, C-C′, D-D′, E-E′, and F-F′ in FIG. 3 are shown in FIGS. 23-28.

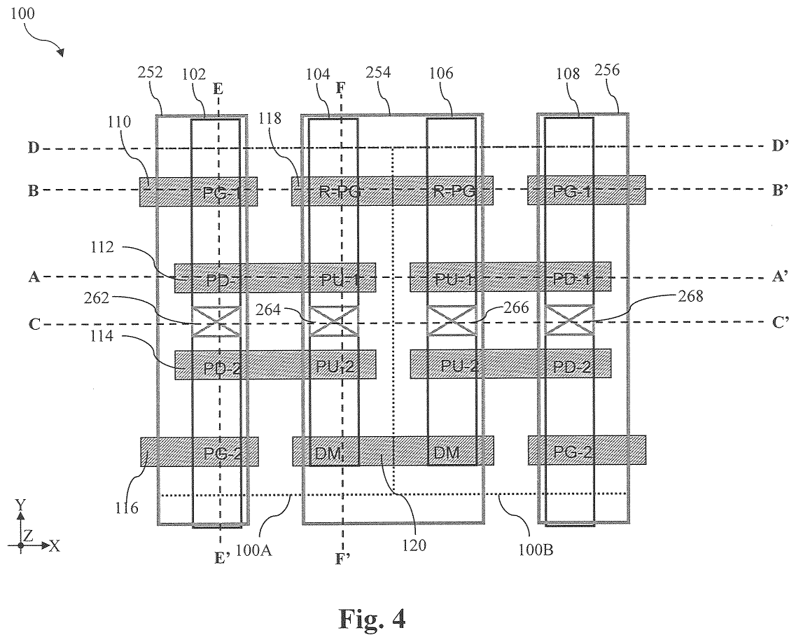

FIG. 4 provides a schematic layout of a first backside metallization layer (BM1) below the dual cell 100 shown in FIG. 2. To provide relative positions, FIG. 4 illustrates the first active region 102, the second active region 104, the third active region 106, and the fourth active region 108. The first backside metallization layer (BM1) includes a first backside reference line 252, a backside power line 254, and a second backside reference line 256. The first backside reference line 252 extends lengthwise along the Y direction below the first active region 102. The first backside reference line 252 is coupled to the source/drain contact 140 (shown in FIG. 3) by way of a backside via 262. The source/drain contact 140 is coupled to the sources of the first pull-down transistor (PD-1) and the second pull-down transistor (PD-2). Like reference line 204, the first backside reference line 252 is coupled to the reference voltage Vss. The backside power line 254 extends lengthwise along the Y direction below the second active region 104 and the third active region 106. The backside power line 254 is coupled to the second long source/drain contact 142 (shown in FIG. 3) by way of a backside vias 264 and 266. The second long source/drain contact 142 is coupled to the sources of the first pull-up transistor (PU-1) and the second pull-up transistor (PU-2). The backside power line 254 is couple to the power supply Vdd. The second backside reference line 256 is a counterpart of the first backside reference line 252 in the second cell 100B.

Fragmentary cross-sectional views of the dual cell 100 along lines A-A′, B-B′, C-C′, D-D′, E-E′, and F-F′ in FIG. 4 are shown in FIGS. 23-28.

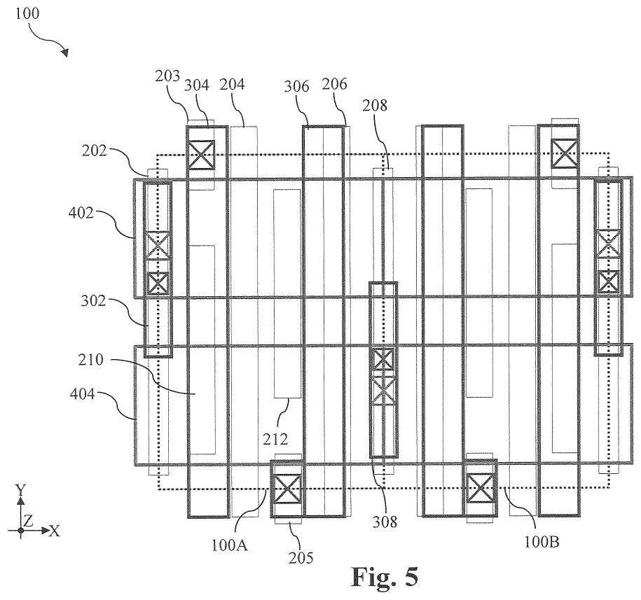

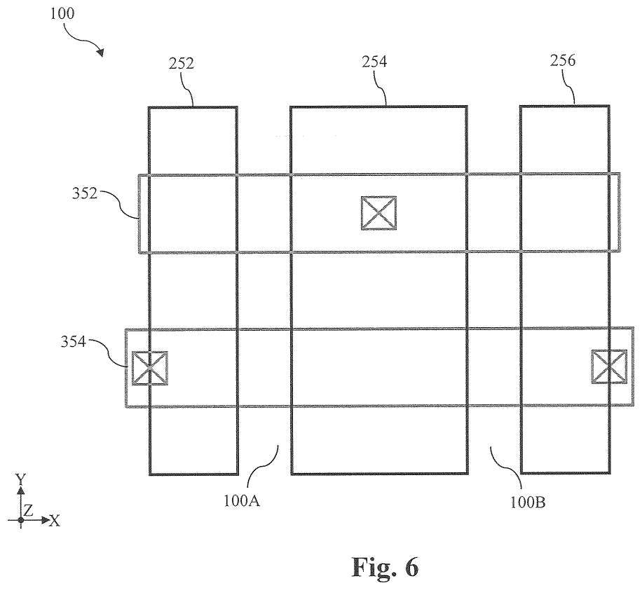

FIGS. 5 and 6 illustrate frontside metallization layers and backside metallization layers according to a first embodiment. FIG. 5 is a schematic layout of a second frontside metallization layer (M2) and a third frontside metallization layer (M3) over the first frontside metallization layer (M1) in FIG. 3. According to the first embodiment, the second frontside metallization layer (M2) includes a write word line (W-WL) landing pad 302, a bit line 304, a complementary bit line 306, and a read word line (R-WL) landing pad 308. The W-WL landing pad 302 extends lengthwise along the Y direction. The W-WL landing pad 302 is disposed over and electrically coupled to the W-WL landing pad 202 by way of a contact via. The bit line 304 extends lengthwise along the Y direction over the write bit line (W-BL) island 203 and the first local interconnect 210 in the first frontside metallization layer (M1). The bit line 304 is electrically coupled to the W-BL island 203 by way of a contact via. The complementary bit line 306 extends lengthwise along the Y direction over the read bit line (R-BL) line 206 in the first frontside metallization layer (M1). The complementary bit line 306 is coupled a jog or a branch portion dispose directly over the write bit line bar (W-BLB) island 205. The jog or the branch portion is also disposed in the second frontside metallization layer (M2). The complementary bit line 306 is coupled to the write bit line bar (W-BLB) island 205 by way of the branch portion and a contact via. The R-WL landing pad 308 extends lengthwise along the Y direction. The R-WL landing pad 308 is disposed over and electrically coupled to the read word line (R-WL) landing pad 208 by way of a contact via. As shown in FIG. 5, because the second cell 100B is a mirror image of the first cell 100A, the metal features in the second frontside metallization layer (M2) over the second cell 100B have corresponding counterparts over the second cell 100B. The first cell 100A and the second cell 100B share the R-WL landing pad 308 over a boundary of the first cell 100A and the second cell 100B.

The third frontside metallization layer (M3) in FIG. 5 includes a write word line (W-WL) 402 and a read word line (R-WL) 404 extending lengthwise along the X direction. The write word line 402 extends over the write word line (W-WL) landing pad 302 in the first cell 100A and a counterpart write word line (W-WL) landing pad in the second cell 100B. The write word line (W-WL) 402 is electrically coupled to the write word line (W-WL) landing pad 302 by way of a contact via. The read word line (R-WL) 404 extends over the R-WL landing pad 308. The read word line (R-WL) 404 is electrically coupled to the R-WL landing pad 308 by a contact via.

FIG. 6 is a schematic layout of first two backside metallization layers below the FEOL layout in FIG. 2. FIG. 6 illustrates a first backside metallization layer (BM1) and a second backside metallization layer (BM2) below the first backside metallization layer (BM1). The routing features in the first backside metallization layer (BM1) have been described above in conjunction with FIG. 4. For brevity, a detailed description of the first backside metallization layer (BM1) is omitted. The second backside metallization layer (BM2) includes a power line 352 and a reference line 354 extending lengthwise along the X direction. The power line 352 is electrically coupled to the backside power line 254 in the first backside metallization layer (BM1) by way of a contact via. The reference line 354 is electrically coupled to the first backside reference line 252 and the second backside reference line 256 by way of contact vias. The power line 352 is electrically coupled to the power supply Vdd. The reference line 354 is electrically coupled to the reference voltage Vss.

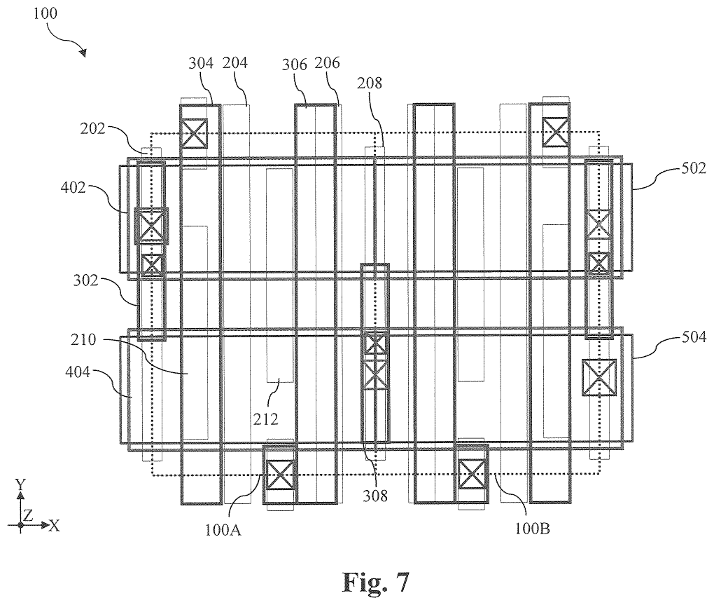

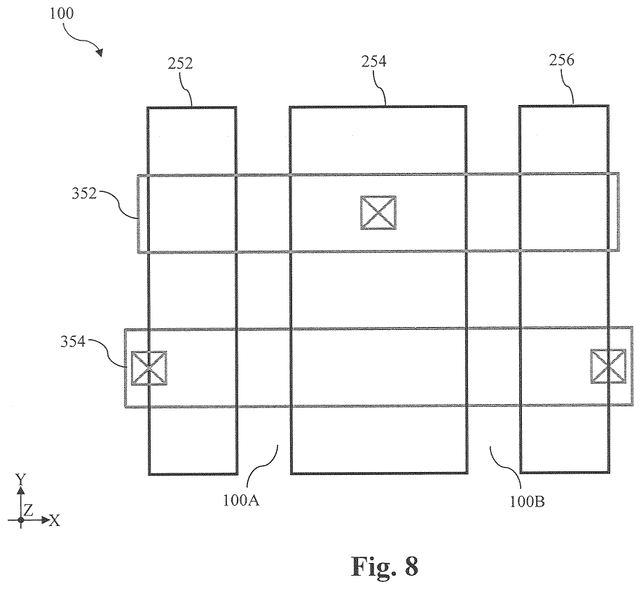

FIGS. 7 and 8 illustrate frontside metallization layers and backside metallization layers according to a second embodiment. FIG. 7 is a schematic layout of a second frontside metallization layer (M2), a third frontside metallization layer (M3), and a fourth frontside metallization layer (M4) over the first frontside metallization layer in FIG. 3. The routing features in the second frontside metallization layer (M2) and the third frontside metallization layer (M3) are similar to the second frontside metallization layer (M2) and the third frontside metallization layer (M3) described above in conjunction with FIG. 5. The fourth frontside metallization layer (M4) in FIG. 7 includes a booster write word line (W-WL) 502 over the write word line (W-WL) 402 and a booster read word line (R-WL) 504 over the read word line (R-WL) 404. The booster write word line (W-WL) 502 is disposed over the write word line (W-WL) 402. The booster write word line (W-WL) 502 is electrically coupled to the write word line (W-WL) 402 by way of one or more contact vias to reduce overall write word line resistance. The booster read word line (R-WL) 504 is disposed over the read word line (R-WL) 404. The booster read word line (R-WL) 504 is electrically coupled to the read word line (R-WL) 404 by way of one or more contact vias to reduce overall read word line resistance.

FIG. 8 is a schematic layout of first two backside metallization layers below the FEOL layout in FIG. 2. The routing features in the first two backside metallization layers are similar to those described in conjunction with FIGS. 4 and 6. A detailed description of the two backside metallization layers in FIG. 8 is omitted for brevity.

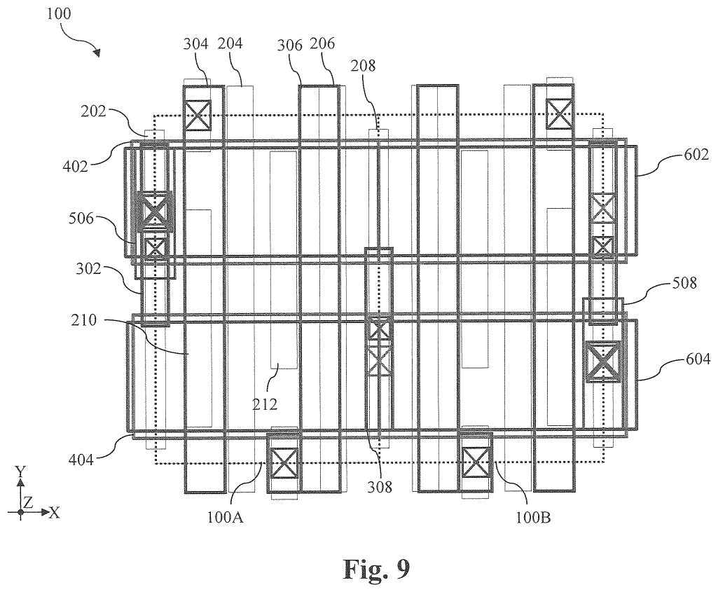

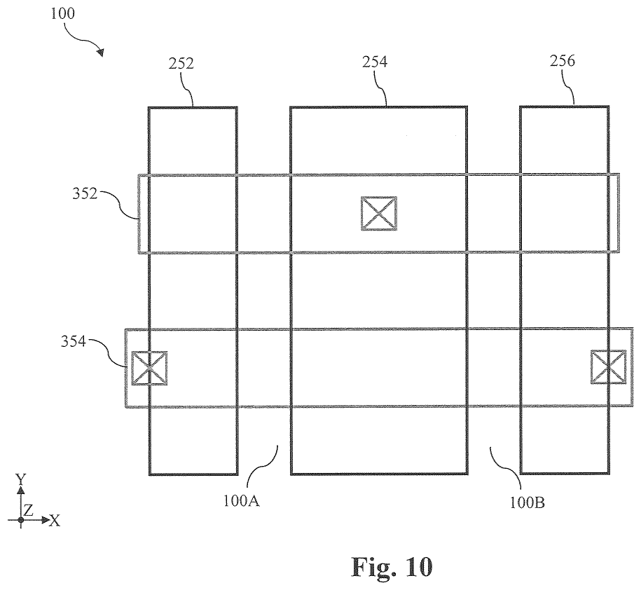

FIGS. 9 and 10 illustrate frontside metallization layers and backside metallization layers according to a third embodiment. FIG. 9 is a schematic layout of a second frontside metallization layer (M2), a third frontside metallization layer (M3), a fourth frontside metallization layer (M4), and a fifth frontside metallization layer (M5) over the first frontside metallization layer in FIG. 3. In the third embodiments, the booster write word line and the booster read word line are disposed in the fifth frontside metallization layer (M5). The booster write word line and the booster read word line are respectively coupled to the write word line (W-WL) 402 and the read word line (R-WL) 404 by way of island pads in the fourth frontside metallization layer (M4). Referring to FIG. 9, the fourth frontside metallization layer (M4) includes a write word line (W-WL) island 506 and a read word line (R-WL) island 508. The write word line (W-WL) island 506 can be anywhere over the write word line (W-WL) 402 to provide vertical electrical coupling. In the depicted embodiments, the write word line (W-WL) island 506 is pushed to an edge of the first cell 100A, directly over the write word line (W-WL) landing pad 302. The read word line (R-WL) island 508 can be anywhere over the read word line (R-WL) 404 to provide vertical electrical coupling. In the depicted embodiments, the read word line (R-WL) island 508 is pushed to an edge of the second cell 100B. In the depicted embodiments, the write word line (W-WL) island 506 and the read word line (R-WL) island 508 are not disposed over a single cell. Rather, one of them is disposed over the first cell 100A and the other is disposed over the second cell 100B.

The fifth frontside metallization layer (M5) in FIG. 9 includes a booster write word line (W-WL) 602 over the write word line (W-WL) 402 and a booster read word line (R-WL) 604 over the read word line (R-WL) 404. The booster write word line (W-WL) 602 is disposed over the write word line (W-WL) 402. The booster word line (W-WL) 602 is electrically coupled to the write word line (W-WL) 402 by way of the write word line (W-WL) island 506 and one or more contact vias to reduce overall write word line resistance. The booster read word line (R-WL) 604 is disposed over the read word line (R-WL) 404. The booster read word line (R-WL) 604 is electrically coupled to the read word line (R-WL) 404 by way of the read word line (R-WL) island 508 and one or more contact vias to reduce overall read word line resistance.

FIG. 10 is a schematic layout of first two backside metallization layers below the FEOL layout in FIG. 2. The routing features in the first two backside metallization layers are similar to those described in conjunction with FIGS. 4 and 6. A detailed description of the two backside metallization layers in FIG. 10 is omitted for brevity.

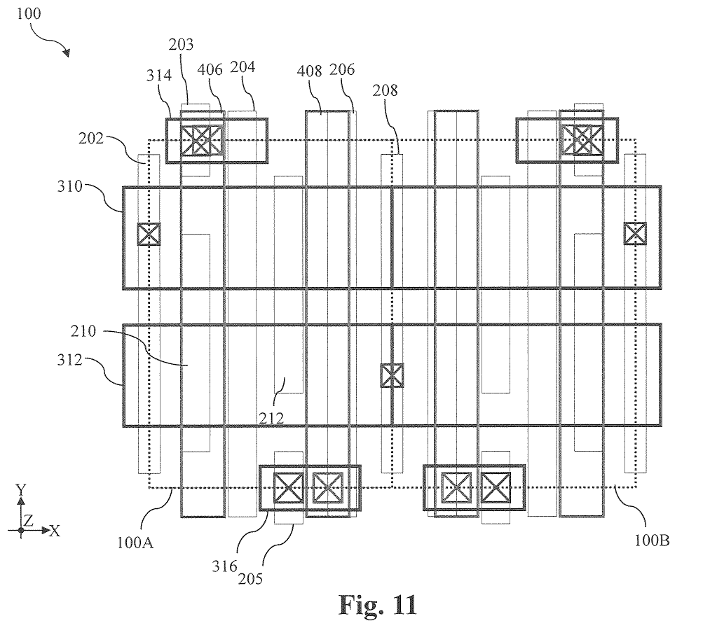

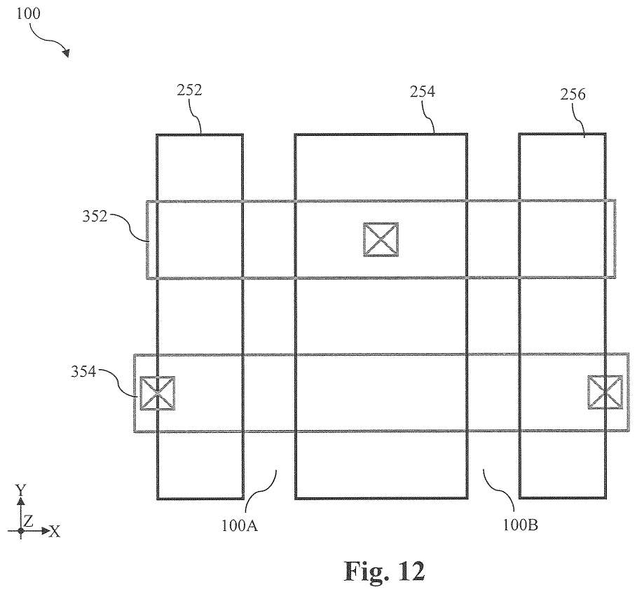

FIGS. 11 and 12 illustrate frontside metallization layers and backside metallization layers according to a fourth embodiment. FIG. 11 is a schematic layout of a second frontside metallization layer (M2) and a third frontside metallization layer (M3) over the first frontside metallization layer (M1) in FIG. 3. According to the fourth embodiment, the second frontside metallization layer (M2) includes a write word line (W-WL) 310, a read word line (R-WL) 312, a bit line island 314, and a complementary bit line island 316. The write word line (W-WL) 310, the read word line (R-WL) 312, the bit line island 314, and the complementary bit line island 316 all extends lengthwise along the X direction. The W-WL 310 extends over the write word line (W-WL) landing pad 202, the reference line 204, the read bit line (R-BL) line 206, and the read word line (R-WL) landing pad 208 and is electrically coupled to the write word line (W-WL) landing pad 202 by way of a contact via. The R-WL 312 extends over the write word line (W-WL) landing pad 202, the reference line 204, the read bit line (R-BL) line 206, and the read word line (R-WL) landing pad 208 and is electrically coupled to the read word line (R-WL) landing pad 208 by way of a contact via. The bit line island 314 in the second frontside metallization layer (M2) is disposed over and electrically coupled to the write bit line (W-BL) island 203. The complementary bit line island 316 in the second frontside metallization layer (M2) is disposed over and electrically coupled to write bit line bar (W-BLB) island 205. The bit line island 314 provides a vertical connection through the second frontside metallization layer (M2), leading to the bit line in the third frontside metallization layer (M3). The complementary bit line island 316 provides a vertical connection through the second frontside metallization layer (M2) ), leading to the complementary bit line in the third frontside metallization layer (M3). The third frontside metallization layer (M3) in FIG. 11 includes a bit line 406 and a complementary bit line 408, both of which extend lengthwise along the Y direction. The bit line 406 in the third frontside metallization layer (M3) extends over the bit line island 314, the write word line (W-WL) 310, and the read word line (R-WL) 312 and is electrically coupled to the bit line island 314 by way of a contact via. The complementary bit line 408 in the third frontside metallization layer (M3) extends over the complementary bit line island 316, the write word line (W-WL) 310, and the read word line (R-WL) 312 and is electrically coupled to the complementary bit line island 316 by way of a contact via. As shown in FIG. 11, because the second cell 100B is a mirror image of the first cell 100A, the routing features in the second frontside metallization layer (M2) and the third frontside metallization layer (M3) over the second cell 100B have corresponding counterparts over the second cell 100B.

FIG. 12 is a schematic layout of first two backside metallization layers below the FEOL layout in FIG. 2. The routing features in the first two backside metallization layers are similar to those described in conjunction with FIGS. 4 and 6. A detailed description of the two backside metallization layers in FIG. 12 is omitted for brevity.

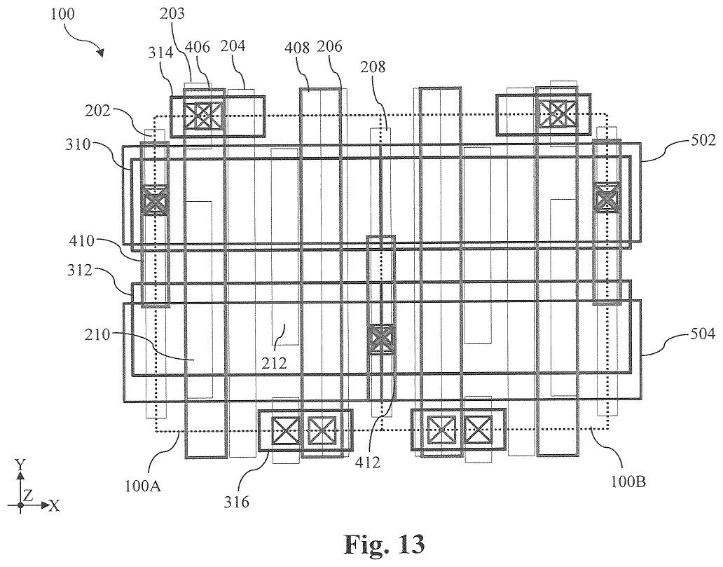

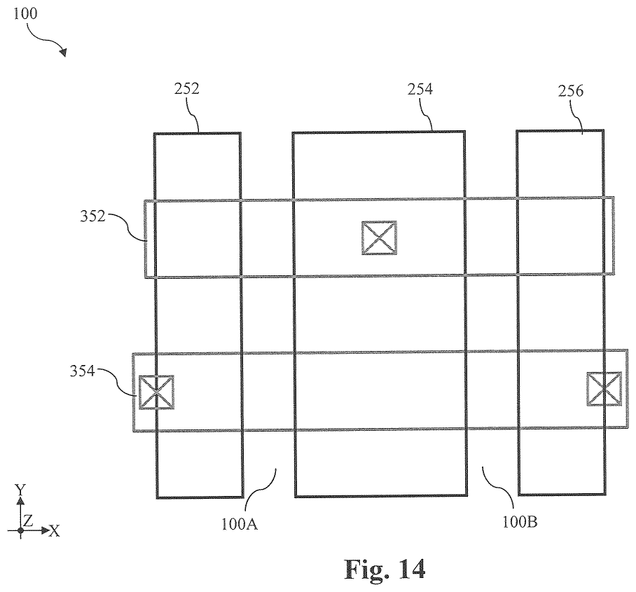

FIGS. 13 and 14 illustrate frontside metallization layers and backside metallization layers according to a fifth embodiment. FIG. 13 is a schematic layout of a second frontside metallization layer (M2) and a third frontside metallization layer (M3) over the first frontside metallization layer in FIG. 3. According to the fifth embodiment, the second frontside metallization layer (M2) includes a write word line (W-WL) 310, a read word line (R-WL) 312, a bit line island 314, and a complementary bit line island 316. The write word line (W-WL) 310, the read word line (R-WL) 312, the bit line island 314, and the complementary bit line island 316 all extends lengthwise along the X direction. The W-WL 310 extends over the write word line (W-WL) landing pad 202, the reference line 204, the read bit line (R-BL) line 206, and the read word line (R-WL) landing pad 208 and is electrically coupled to the write word line (W-WL) landing pad 202 by way of a contact via. The R-WL 312 extends over the write word line (W-WL) landing pad 202, the reference line 204, the read bit line (R-BL) line 206, and the read word line (R-WL) landing pad 208 and is electrically coupled to the read word line (R-WL) landing pad 208 by way of a contact via. The bit line island 314 in the second frontside metallization layer (M2) is disposed over and electrically coupled to the write bit line (W-BL) island 203. The complementary bit line island 316 in the second frontside metallization layer (M2) is disposed over and electrically coupled to write bit line bar (W-BLB) island 205. The bit line island 314 provides a vertical connection through the second frontside metallization layer (M2), leading to the bit line in the third frontside metallization layer (M3). The complementary bit line island 316 provides a vertical connection through the second frontside metallization layer (M2), leading to the complementary bit line in the third frontside metallization layer (M3).

The third frontside metallization layer (M3) in FIG. 13 includes a bit line 406, a complementary bit line 408, a write word line (W-WL) island 410, a read word line (R-WL) island 412, all of which extend lengthwise along the Y direction. The bit line 406 in the third frontside metallization layer (M3) extends over the bit line island 314, the write word line (W-WL) 310, and the read word line (R-WL) 312 and is electrically coupled to the bit line island 314 by way of a contact via. The complementary bit line 408 in the third frontside metallization layer (M3) extends over the complementary bit line island 316, the write word line (W-WL) 310, and the read word line (R-WL) 312 and is electrically coupled to the complementary bit line island 316 by way of a contact via. The write word line (W-WL) island 410 is disposed over the write word line (W-WL) 310 and the write word line (W-WL) landing pad 202. The write word line (W-WL) island 410 is electrically coupled to the write word line (W-WL) 310 by way of a contact via. The R-WL island 412 is disposed over the read word line (R-WL) 312 and read word line (R-WL) landing pad 208. The R-WL island 412 is electrically coupled to the read word line (R-WL) 312 by way of a contact via. As shown in FIG. 13, because the second cell 100B is a mirror image of the first cell 100A, the routing features in the second frontside metallization layer (M2) and the third frontside metallization layer (M3) over the second cell 100B have corresponding counterparts over the second cell 100B.

FIG. 14 is a schematic layout of first two backside metallization layers below the FEOL layout in FIG. 2. The routing features in the first two backside metallization layers are similar to those described in conjunction with FIGS. 4 and 6. A detailed description of the two backside metallization layers in FIG. 14 is omitted for brevity.

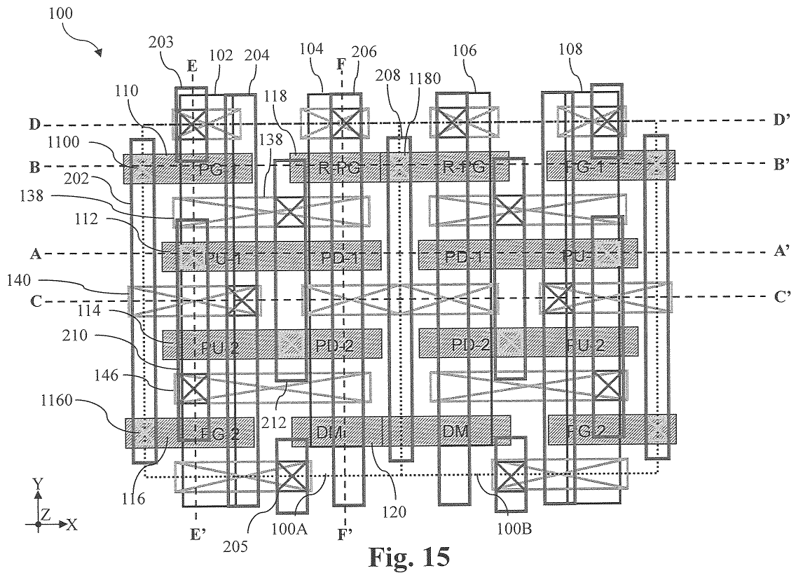

FIG. 15 is a schematic layout of a first frontside metallization layer over an alternative FEOL layout, according to various aspects of the present disclosure. In the alternative FEOL layout shown in FIG. 15, the first pass-gate transistor (PG-1), the second pass-gate transistor (PG-2), the first pull-up transistor (PU-1), and the second pull-up transistor (PU-2) are p-type multi-gate transistors source/drain features including silicon germanium (SiGe) and a p-type dopant, such as boron (B). The read pass-gate transistor (R-PG), the first pull-down transistor (PD-1), the second pull-down transistor (PD-2), and the dummy transistor (DM) are n-type multi-gate transistors having source/drain features including silicon (Si) and an n-type dopant, such as phosphorus (P) or arsenic (As). Other than the conductivities of the transistors, the first frontside metallization layer (m1) and the alternative FEOL layout in FIG. 15 are similar to those shown in FIG. 3.

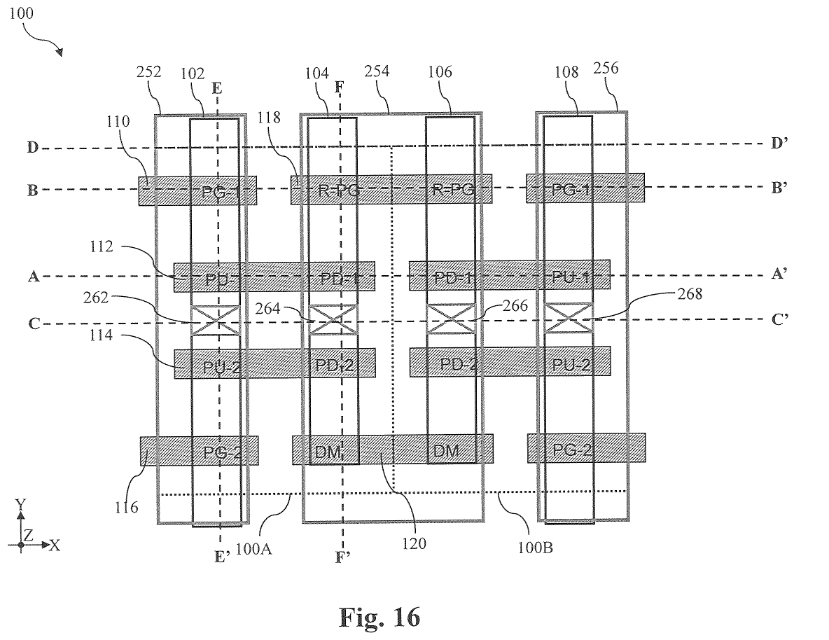

FIG. 16 is a schematic layout of a first backside metallization layer (BM1) below the alternative FEOL layout shown in FIG. 15. The routing features in the first backside metallization layer (BM1) have been described above in conjunction with FIG. 4. For brevity, a detailed description of the first backside metallization layer (BM1) in FIG. 16 is omitted.

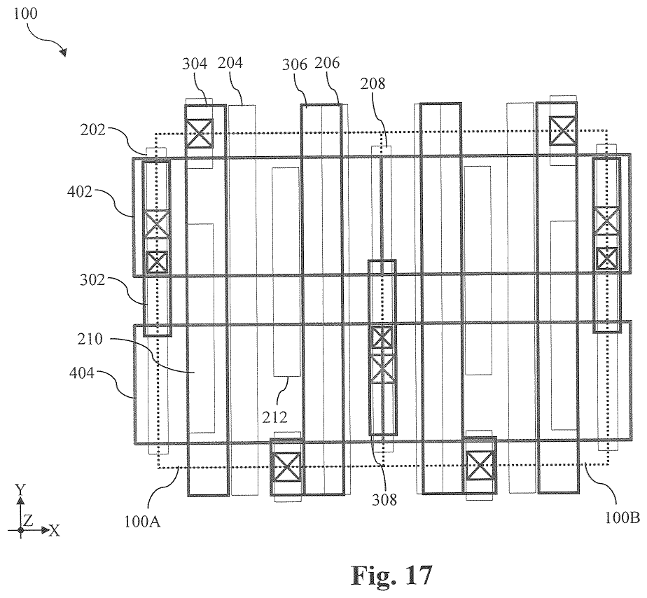

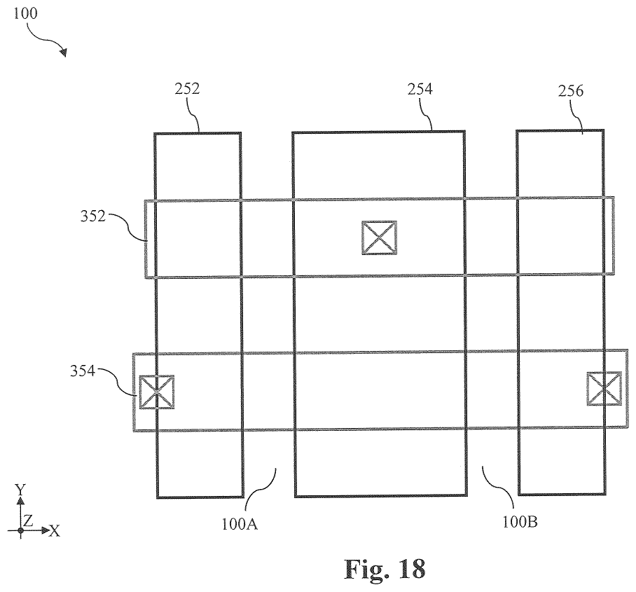

FIGS. 17 and 18 illustrate frontside metallization layers and backside metallization layers according to a sixth embodiment. FIG. 17 is a schematic layout of a second frontside metallization layer (M2) and a third frontside metallization layer (M3) over the first frontside metallization layer (M1) in FIG. 15. The routing features in the second frontside metallization layer (M2) and the third frontside metallization layer (M3) are similar to the second frontside metallization layer (M2) and the third frontside metallization layer (M3) described above in conjunction with FIG. 5. A detailed description of the second frontside metallization layer (M2) and the third frontside metallization layer (M3) in FIG. 17 is omitted for brevity.

FIG. 18 is a schematic layout of first two backside metallization layers below the alternative FEOL layout in FIG. 15. The routing features in the first two backside metallization layers are similar to those described in conjunction with FIGS. 4 and 6. A detailed description of the two backside metallization layers in FIG. 18 is omitted for brevity.

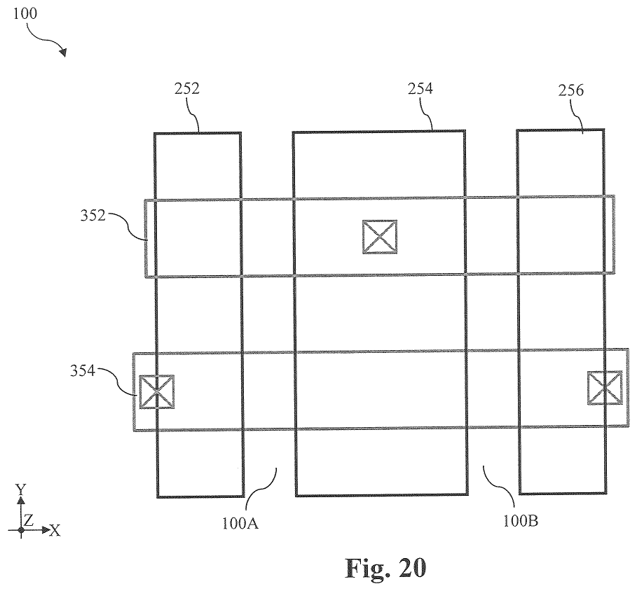

FIGS. 19 and 20 illustrate frontside metallization layers and backside metallization layers according to a seventh embodiment. FIG. 19 is a schematic layout of a second frontside metallization layer (M2), a third frontside metallization layer (M3), and a fourth frontside metallization layer (M4) over the first frontside metallization layer (M1) in FIG. 15. The routing features the second frontside metallization layer (M2), the third frontside metallization layer (M3), and the fourth frontside metallization layer (M4) are similar to the second frontside metallization layer (M2), the third frontside metallization layer (M3), and the fourth frontside metallization layer (M4) described above in conjunction with FIG. 7. A detailed description of the second frontside metallization layer (M2), the third frontside metallization layer (M3), and the fourth frontside metallization layer (M4) in FIG. 19 is omitted for brevity.

FIG. 20 is a schematic layout of first two backside metallization layers below the alternative FEOL layout in FIG. 15. The routing features in the first two backside metallization layers are similar to those described in conjunction with FIGS. 4 and 6. A detailed description of the two backside metallization layers in FIG. 20 is omitted for brevity.

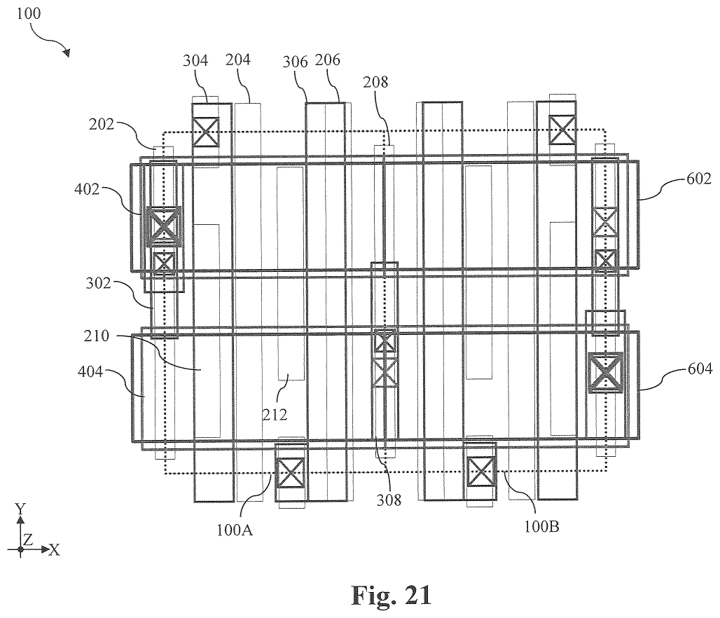

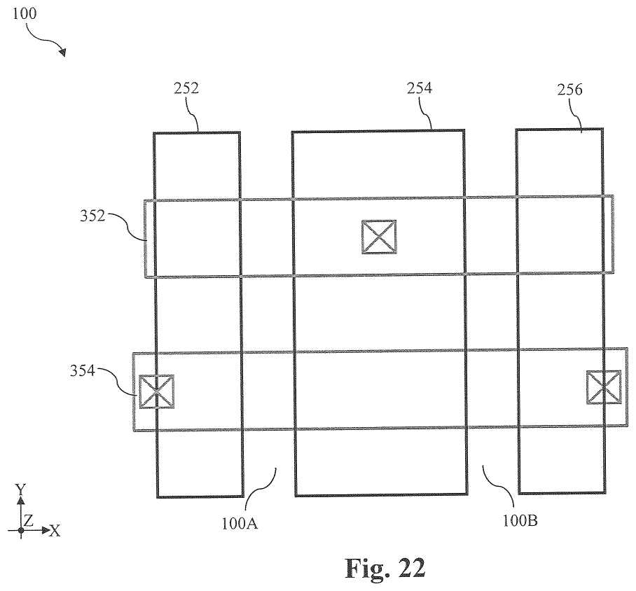

FIGS. 21 and 22 illustrate frontside metallization layers and backside metallization layers according to an eighth embodiment. FIG. 21 is a schematic layout of a second frontside metallization layer (M2), a third frontside metallization layer (M3), a fourth frontside metallization layer (M4), and a fifth frontside metallization layer (M5) over the first frontside metallization layer in FIG. 15. The routing features the second frontside metallization layer (M2), the third frontside metallization layer (M3), the fourth frontside metallization layer (M4), and the fifth frontside metallization layer (M5) are similar to the second frontside metallization layer (M2), the third frontside metallization layer (M3), the fourth frontside metallization layer (M4), and the fifth frontside metallization layer (M5) described above in conjunction with FIG. 9. A detailed description of the second frontside metallization layer (M2), the third frontside metallization layer (M3), the fourth frontside metallization layer (M4), and the fifth frontside metallization layer (M5) in FIG. 21 is omitted for brevity.

FIG. 22 is a schematic layout of first two backside metallization layers below the alternative FEOL layout in FIG. 15. The routing features in the first two backside metallization layers are similar to those described in conjunction with FIGS. 4 and 6. A detailed description of the two backside metallization layers in FIG. 22 is omitted for brevity.

FIG. 23 is a schematic cross-sectional view along line A-A′ in FIGS. 3 and 4. Reference is first made to FIGS. 3 and 4. Line A-A′ cuts through the first backside reference line 252, the backside power line 254, the second backside reference line 256, the first pull-down transistor (PD-1) over the first active region 102, the first pull-up transistor (PU-1) over the second active region 104, the second gate structure 112, the W-WL landing pad 202, the first local interconnect 210, the reference line 204, the second local interconnect 212, the read bit line (R-BL) line 206, and the read word line (R-WL) landing pad 208. The first backside reference line 252, the backside power line 254, and the second backside reference line 256 are disposed in a backside IMD layer 124. A channel region of the first pull-down transistor (PD-1) includes a base portion 150B disposed in an isolation feature 122 and a plurality of channel members 150 over the base portion 150B. The isolation feature 122 may also be referred to as a shallow trench isolation (STI) feature 122. The second gate structure 112 is disposed between a first gate isolation feature 130 and a second gate isolation feature 132. The first gate isolation feature 130 and the second gate isolation feature 132 partially extend into the isolation feature 122. An interlayer dielectric (ILD) layer 126 is disposed over the second gate structure 112, the first gate isolation feature 130 and the second gate isolation feature 132. A frontside IMD layer 128 is disposed over the ILD layer 126. The W-WL landing pad 202, the first local interconnect 210, the reference line 204, the second local interconnect 212, the write bit line bar (W-BLB) island 205, the read bit line (R-BL) line 206, and the read word line (R-WL) landing pad 208 are disposed in the frontside IMD layer 128.

The backside IMD layer 124, the isolation feature 122, and the frontside IMD layer 128 may include an oxide-based material or a low-k dielectric material. In some instances, the backside IMD layer 124, the isolation feature 122, and the frontside IMD layer 128 includes silicon oxide. In some embodiments, the base portion 150B and the channel members 150 include silicon (Si). A channel region of the first pull-up transistor (PU-1) is formed from the second active region 104 and may include similar structures as the channel region of the first pull-down (PD-1) transistor. The second gate structure 112 extends lengthwise along the X to wrap around each of the channel members 150 in the channel regions of the first pull-down transistor (PD-1) and the first pull-up transistor (PU-1). In the depicted embodiments, the second gate structure 112 includes a gate dielectric layer 152 interfacing surfaces of the channel members 150 and a gate electrode 154 over the gate dielectric layer 152. In some embodiments, the gate dielectric layer 152 includes a high-k dielectric material, such as hafnium oxide, zirconium oxide, lanthanum oxide, aluminum oxide, or a combination thereof. A dielectric constant of the gate dielectric layer 152 is greater than a dielectric constant of the backside IMD layer 124, the isolation feature 122, or the frontside IMD layer 128. In some instances, the dielectric constant of the gate dielectric layer 152 is between about 2 times and about 4 times of the dielectric constant of the backside IMD layer 124, the isolation feature 122, or the frontside IMD layer 128. The gate electrode 154 includes an n-type work function layer, a p-type work function layer, a glue layer, a cap layer, and a gate fill. Because both an n-type work function layer and a p-type work function layer include a titanium-containing conductive material, the gate electrode 154 includes a titanium-based material. The second gate structure 112 extends over and interfaces the isolation feature 122. The isolation feature 122 interfaces sidewalls of the base portion 150B, sidewalls of the first gate isolation feature 130, and sidewalls of the second gate isolation feature 132. The first gate isolation feature 130 and the second gate isolation feature 132 includes a dielectric material having a dielectric constant greater than that of silicon oxide. In some embodiments, the first gate isolation feature 130 and the second gate isolation feature 132 includes silicon nitride, silicon oxynitride, or silicon oxycarbonitride. In some implementations, each of the first gate isolation feature 130 and the second gate isolation feature 132 may include an inner layer and outer layer. A dielectric constant of the outer layer is greater than a dielectric constant of the inner layer. In these implementations, the inner layer includes silicon oxide and the outer layer includes silicon nitride. Because the second cell 100B is a mirror image of the first cell 100A, the foregoing description also applies to corresponding structures in the second cell 100B.

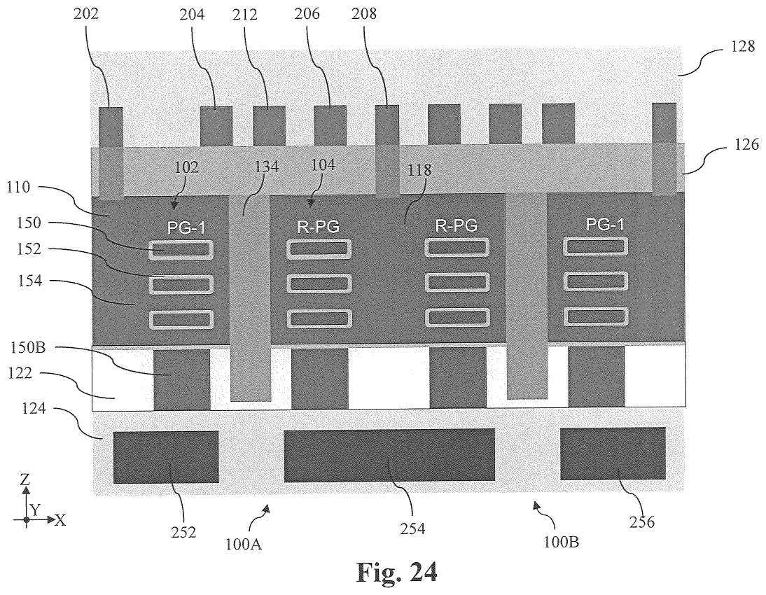

FIG. 24 is a schematic cross-sectional view along line B-B′ in FIGS. 3 and 4. Line B-B′ cuts through the first backside reference line 252, the backside power line 254, the second backside reference line 256, the first pass-gate (PG-1) over the first active region 102, the read pass-gate transistor (R-PG) over the second active region 104, the first gate structure 110, the fifth gate structure 118, the W-WL landing pad 202, the reference line 204, the second local interconnect 212, the read bit line (R-BL) line 206, and the read word line (R-WL) landing pad 208. The first backside reference line 252, the backside power line 254, and the second backside reference line 256 are disposed in the backside IMD layer 124. A channel region of the first pass-gate transistor (PG-1) includes a base portion 150B disposed in the isolation feature 122 and a plurality of channel members 150 over the base portion 150B. The first gate structure 110 is isolated from the fifth gate structure 118 by a third gate isolation feature 134. The third gate isolation feature 134 partially extends into the isolation feature 122. The interlayer dielectric (ILD) layer 126 is disposed over the first gate structure 110, the third gate isolation feature 134 and the fifth gate structure 118. The frontside IMD layer 128 is disposed over the ILD layer 126. The W-WL landing pad 202, the reference line 204, the second local interconnect 212, the read bit line (R-BL) line 206, and the read word line (R-WL) landing pad 208 are disposed in the frontside IMD layer 128. Throughout the present disclosure, like reference numerals are used to denote like structures. Detailed descriptions of features in FIG. 24 that have been described above in conjunction with FIG. 23 are omitted here for brevity.

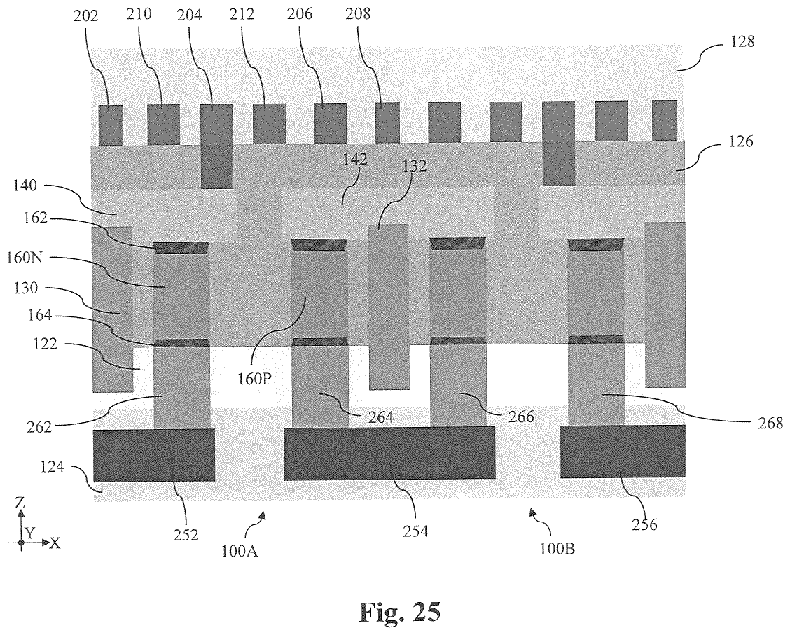

FIG. 25 is a schematic cross-sectional view along line C-C′ in FIGS. 3 and 4. Line C-C′ cuts through the first backside reference line 252, the backside power line 254, the second backside reference line 256, an n-type source/drain feature 160N over the first active region 102, a p-type source/drain feature 160P over the second active region 104, the source/drain contact 140, the second long source/drain contact 142, the W-WL landing pad 202, the first local interconnect 210, the reference line 204, the second local interconnect 212, the read bit line (R-BL) line 206, and the read word line (R-WL) landing pad 208. The first backside reference line 252, the backside power line 254, and the second backside reference line 256 are disposed in the backside IMD layer 124. The n-type source/drain feature 160N is shared by the first pull-down transistor (PD-1) and the second pull-down transistor (PD-2). The n-type source/drain feature 160N includes silicon (Si) and an n-type dopant, such as phosphorus (P) or arsenic (As). The p-type source/drain feature 160P is shared by the first pull-up transistor (PU-1) and the second pull-up transistor (PU-2). The p-type source/drain feature 160P includes silicon germanium (SiGe) and a p-type dopant, such as boron (B). The n-type source/drain feature 160N is electrically coupled to the first backside reference line 252 by way of the backside via 262. The backside via 262 interfaces a bottom surface of the n-type source/drain feature 160N by way of a backside silicide feature 164. The p-type source/drain feature 160P is electrically coupled to the backside power line 254 by way of the backside via 264. The backside via 264 interfaces a bottom surface of the p-type source/drain feature 160P by way of another backside silicide feature 164. The n-type source/drain feature 160N is also electrically coupled to the source/drain contact 140 by way of a frontside silicide feature 162. The p-type source/drain feature 160P is also electrically coupled to the second long source/drain contact 142 by way of another frontside silicide feature 162. The interlayer dielectric (ILD) layer 126 is disposed over the source/drain contact 140 and the second long source/drain contact 142. The frontside IMD layer 128 is disposed over the ILD layer 126. The W-WL landing pad 202, the first local interconnect 210, the reference line 204, the second local interconnect 212, the read bit line (R-BL) line 206, and the read word line (R-WL) landing pad 208 are disposed in the frontside IMD layer 128. In some embodiments, the frontside silicide feature 162 and the backside silicide feature 164 include titanium silicide. The source/drain contact 140 and the second long source/drain contact 142 includes cobalt (Co), nickel (Ni), ruthenium (Ru), or tungsten (W). The frontside silicide features 162 and the backside silicide features 164 provide a low contact resistance interface to the source/drain features. An electrical conductivity of the frontside silicide features 162 and the backside silicide features 164 is smaller than an electrical conductivity of the source/drain contact 140 and the second long source/drain contact 142, which are formed of metal. Throughout the present disclosure, like reference numerals are used to denote like structures. Detailed descriptions of features in FIG. 25 that have been described above in conjunction with FIG. 23 are omitted here for brevity.

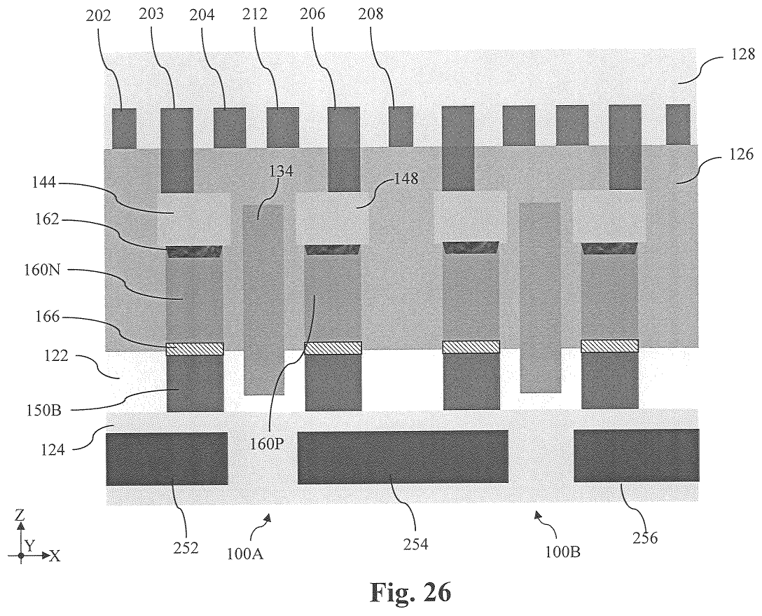

FIG. 26 is a schematic cross-sectional view along line D-D′ in FIGS. 3 and 4. Line D-D′ cuts through the first backside reference line 252, the backside power line 254, the second backside reference line 256, an n-type source/drain feature 160N over the first active region 102, a p-type source/drain feature 160P over the second active region 104, a source/drain contact 144, a source/drain contact 148, the W-WL landing pad 202, the write bit line (W-BL) island 203, the reference line 204, the second local interconnect 212, the read bit line (R-BL) line 206, and the read word line (R-WL) landing pad 208. The first backside reference line 252, the backside power line 254, and the second backside reference line 256 are disposed in the backside IMD layer 124. The n-type source/drain feature 160N interfaces channel members 150 of the first pass-gate transistor (PG-1). The n-type source/drain feature 160N includes silicon (Si) and an n-type dopant, such as phosphorus (P) or arsenic (As). The p-type source/drain feature 160P interfaces channel members 150 of the read pass-gate transistor (R-PG). The p-type source/drain feature 160P includes silicon germanium (SiGe) and a p-type dopant, such as boron (B). The n-type source/drain feature 160N is disposed over a base portion 150B of the first active region 102. The n-type source/drain feature 160N is isolated from the base portion 150B by a bottom dielectric layer 166. The p-type source/drain feature 160P is disposed over a base portion 150B of a base portion 150B. The p-type source/drain feature 160P is isolated from the base portion 150B by another bottom dielectric layer 166. In some embodiments, the bottom dielectric layers 166 may include silicon nitride. The n-type source/drain feature 160N is also electrically coupled to the source/drain contact 144 by way of a frontside silicide feature 162. The p-type source/drain feature 160P is also electrically coupled to the source/drain contact 148 by way of another frontside silicide feature 162. The interlayer dielectric (ILD) layer 126 is disposed over the source/drain contact 144 and the source/drain contact 148. The frontside IMD layer 128 is disposed over the ILD layer 126. The W-WL landing pad 202, the write bit line (W-BL) island 203, the first local interconnect 210, the reference line 204, the second local interconnect 212, the read bit line (R-BL) line 206, and the read word line (R-WL) landing pad 208 are disposed in the frontside IMD layer 128. In some embodiments, the frontside silicide features 162 include titanium silicide. The source/drain contact 144 and the source/drain contact 148 includes cobalt (Co), nickel (Ni), ruthenium (Ru), or tungsten (W). The frontside silicide features 162 provide a low contact resistance interface. An electrical conductivity of the frontside silicide features 162 is smaller than an electrical conductivity of the source/drain contacts 144 and 148, which are formed of metal. Throughout the present disclosure, like reference numerals are used to denote like structures. Detailed descriptions of features in FIG. 26 that have been described above in conjunction with FIG. 23 are omitted here for brevity.

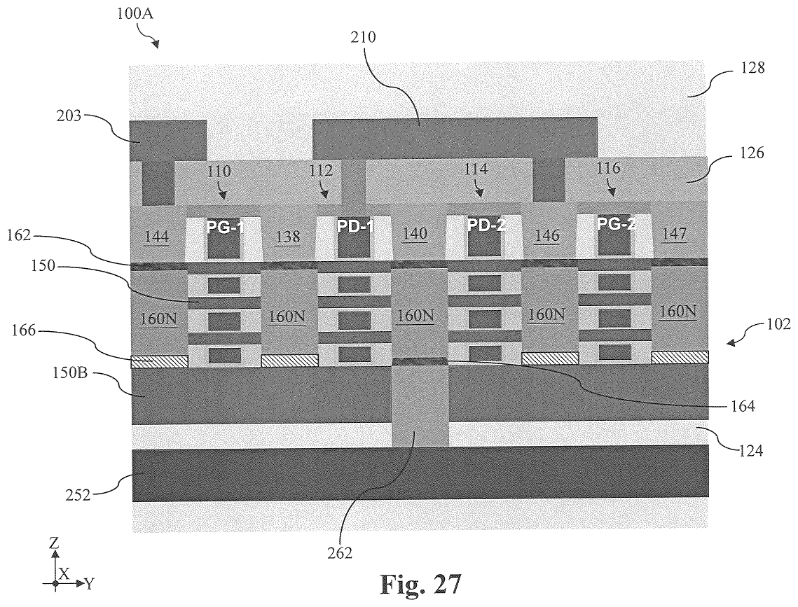

FIG. 27 is a schematic cross-sectional view along line E-E′ in FIGS. 3 and 4. Line E-E′ cuts through the first backside reference line 252, the backside via 262, the first pass-gate transistor (PG-1), the first pull-down transistor (PD-1), the second pull-down transistor (PD-2), the second pass-gate transistor (PG-2), the write bit line (W-BL) island 203, and the first local interconnect 210. In the depicted embodiments, all transistors in the first cell 100A are gate-all-around (GAA) transistors. The first pass-gate transistor (PG-1) includes the first gate structure 110 wrapping around each of the channel members 150 disposed over the base portion 150B of the first active region 102. The first pull-down transistor (PD-1) includes the second gate structure 112 wrapping around each of the channel members 150 disposed over the base portion 150B of the first active region 102. The second pull-down transistor (PD-2) includes the third gate structure 114 wrapping around each of the channel members 150 disposed over the base portion 150B. The second pass-gate transistor (PG-2) includes the fourth gate structure 116 wrapping around each of the channel members 150 disposed over the base portion 150B of the first active region 102. The n-type source/drain feature 160N shared by the first pull-down transistor (PD-1) and the second pull-down transistor (PD-2) is electrically coupled to the first backside reference line 252 by way of the backside via 262. In the embodiments represented in FIG. 27, the other n-type source/drain features 160N are spaced apart from the base portion 150B by the bottom dielectric layer 166. The first backside reference line 252 is disposed in the backside IMD layer 124. The source/drain contact 144 of the first pass-gate transistor (PG-1) is electrically coupled to the write bit line (W-BL) island 203. The first local interconnect 210 electrically couples the second gate structure 112 to the third long source/drain contact 146. The ILD layer 126 is disposed over the first pass-gate transistor (PG-1), the first pull-down transistor (PD-1), the second pull-down transistor (PD-2), and the second pass-gate transistor (PG-2).

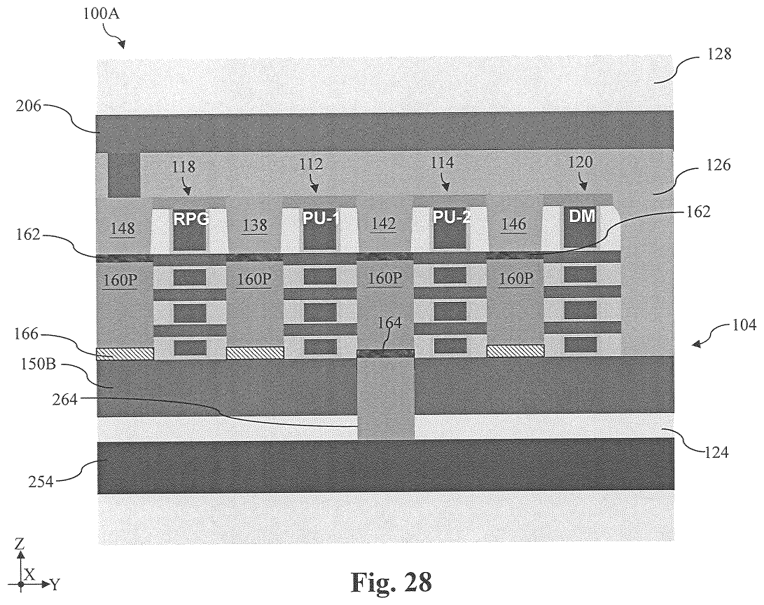

FIG. 28 is a schematic cross-sectional view along line F-F′ in FIGS. 3 and 4. Line F-F's cuts through the read bit line (R-BL) line 206, the backside power line 254, the backside via 264, the read pass-gate transistor (R-PG), the first pull-up transistor (PU-1), the second pull-up transistor (PU-2), the dummy transistor (DM), the p-type source/drain features 160P of these transistors, and source/drain contacts of the p-type source/drain features 160P. The read pass-gate transistor (R-PG) includes the fifth gate structure 118 wrapping around each of the channel members 150 disposed over the base portion 150B of the second active region 104. The first pull-up transistor (PU-1) includes the second gate structure 112 wrapping around each of the channel members 150 disposed over the base portion 150B of the second active region 104. The second pull-up transistor (PD-2) includes the third gate structure 114 wrapping around each of the channel members 150 disposed over the base portion 150B in the second active region 104. The dummy transistor (DM) includes the sixth gate structure 120 wrapping around each of the channel members 150 disposed over the base portion 150B of the second active region 104. The p-type source/drain feature 160P of the read pass-gate transistor (R-PG) is electrically coupled to the read bit line (R-BL) line 206 by way of the source/drain contact 148 and a contact via. The p-type source/drain feature 160P shared by the first pull-up transistor (PU-1) and the second pull-up transistor (PU-2) is coupled to the backside power line 254 by way of the backside via 164. In the embodiments represented in FIG. 28, the other p-type source/drain features 160P not coupled to the backside power line 254 are spaced apart from the base portion 150B by the bottom dielectric layer 166. The backside power line 254 is disposed in the backside IMD layer 124. The ILD layer 126 is disposed over the read pass-gate transistor (R-PG), the first pull-up transistor (PU-1), the second pull-up transistor (PU-2), the dummy transistor (DM). As described above, the second active region 104 is shorter than the first active region 102 along the Y direction. This is shown in FIG. 28. The sixth gate structure of the dummy transistor (DM) is electrically floating and the channel members 150 of the dummy transistor (DM) are not disposed between two p-type source/drain features 160P. Due to lack of one of the source/drain features, the channel members 150 of the dummy transistor (DM) extend, along the Y direction, between a p-type source/drain feature 160P and the ILD layer 126.

The cross-sectional views in FIGS. 23-28 generally applies to a 2P SRAM cell having the alternative FEOL layout shown in FIG. 15 with one exception regarding the conductivity-types of the first pass-gate transistor (PG-1), the first pull-down transistor (PU-1), the second pull-down transistor (PD-1), the second pass-gate transistor (PG-2), the read pass-gate transistor (R-PG), the first pull-up transistor (PU-1), the second pull-up transistor (PU-2), and the dummy transistor (DM). In the alternative FEOL layout, the first pass-gate transistor (PG-1), the first pull-down transistor (PU-1), the second pull-down transistor (PD-1), the second pass-gate transistor (PG-2) are p-type devices with p-type source/drain features 160P. Also, in the alternative FEOL layout, the read pass-gate transistor (R-PG), the first pull-up transistor (PU-1), the second pull-up transistor (PU-2), and the dummy transistor (DM) are n-type devices with n-type source/drain features 160P. For example, when the alternative FEOL layout is adopted, the channel members of the dummy transistor (DM) extend, along the Y direction, between an n-type source/drain feature 160N and the ILD layer 126.

Thus, in one aspect, the present disclosure provides a memory device. The memory device includes a first pass-gate device (PG-1), a first pull-down device (PD-1), a second pull-down device (PD-2), and a second pass-gate device (PG-2) disposed over a first active region extending lengthwise along a first direction, and a read pass-gate device (R-PG), a first pull-up device (PU-1), a second pull-up device (PU-2), and a dummy device disposed over a second active region extending lengthwise along the first direction. A first gate structure of a first pass-gate device (PG-1) is isolated from a second gate structure of the read pass-gate device (R-PG). The first pull-down device (PD-1) and the first pull-up device (PU-1) share a third gate structure. The second pull-down device (PD-2) and the second pull-up device (PU-2) share a fourth gate structure. A fifth gate structure of the second pass-gate device (PG-2) is isolated from a sixth gate structure of the dummy device. A length of the first active region is greater than a length of the second active region. Each of the first gate structure, the second gate structure, the third gate structure, the fourth gate structure, the fifth gate structure, and the sixth gate structure includes a gate dielectric layer and a gate electrode over the gate dielectric layer. The gate electrode includes a titanium-based material.

In some embodiments, the memory device further includes a first frontside metallization layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device. The first frontside metallization layer includes a reference voltage line extending along the first direction over the first gate structure, the third gate structure, the fourth gate structure, and the fifth gate structure, and a read bit line extending along the first direction over the second gate structure, the third gate structure, the fourth gate structure, and the sixth gate structure. In some implementations, the memory device further includes a second frontside metallization layer over the first frontside metallization layer. The second frontside metallization layer includes a first bit line extending along the first direction over the first gate structure, the third gate structure, the fourth gate structure, and the fifth gate structure, and a second bit line extending along the first direction over the read bit line. In some embodiments, the memory device further includes a third frontside metallization layer over the second frontside metallization layer. The third frontside metallization layer includes a first word line extending, along a second direction perpendicular to the first direction, over the first bit line and the second bit line, and a second word line extending along the second direction over the first bit line and the second bit line. In some embodiments, the memory device further includes a fourth frontside metallization layer over the third frontside metallization layer. The fourth frontside metallization layer includes a third word line extending along the second direction over the first word line, and a fourth word line extending along the second direction over the second word line. In some instances, the memory device further includes a fourth frontside metallization layer over the third frontside metallization layer, and a fifth frontside metallization layer over the fourth frontside metallization layer. The fifth frontside metallization layer includes a third word line extending along the second direction over the first word line, and a fourth word line extending along the second direction over the second word line. In some embodiments, the fourth frontside metallization layer includes an island vertically disposed between the first word line and the third word line. In some embodiments, the memory device further includes an interlayer dielectric (ILD) layer over the first gate structure, the second gate structure, the third gate structure, the fourth gate structure, the fifth gate structure, and the sixth gate structure. The dummy device includes a plurality of nanostructures, the sixth gate structure wrapping around each of the plurality of nanostructures, and a source/drain feature interfacing sidewalls of the plurality of nanostructures. The plurality of nanostructures extends between the source/drain feature and the ILD layer along the first direction. In some instances, the sixth gate structure is electrically floating.

In another aspect, the present disclosure provides a memory device. The memory device includes a first pass-gate device (PG-1), a first pull-down device (PD-1), a second pull-down device (PD-2), and a second pass-gate device (PG-2) disposed over a first active region extending lengthwise along a first direction, a read pass-gate device (R-PG), a first pull-up device (PU-1), a second pull-up device (PU-2), and a dummy device disposed over a second active region extending lengthwise along the first direction, and an interlayer dielectric (ILD) layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device. A first gate structure of a first pass-gate device (PG-1) is isolated from a second gate structure of the read pass-gate device (R-PG). The first pull-down device (PD-1) and the first pull-up device (PU-1) share a third gate structure. The second pull-down device (PD-2) and the second pull-up device (PU-2) share a fourth gate structure. A fifth gate structure of the second pass-gate device (PG-2) is isolated from a sixth gate structure of the dummy device. The dummy device includes a plurality of nanostructures, the sixth gate structure wrapping around each of the plurality of nanostructures, and a source/drain feature interfacing sidewalls of the plurality of nanostructures. The plurality of nanostructures extends between the source/drain feature and the ILD layer along the first direction. A source/drain contact is disposed over the source/drain feature. A silicide layer is disposed between the source/drain contact and the source/drain feature and an electrical conductivity of the source/drain contact is greater than an electrical conductivity of the silicide layer.

In some embodiments, The memory device further includes a first frontside metallization layer over the ILD layer. The first frontside metallization layer includes a reference voltage line extending along the first direction over the first gate structure, the third gate structure, the fourth gate structure, and the fifth gate structure, and a read bit line extending along the first direction over the second gate structure, the third gate structure, the fourth gate structure, and the sixth gate structure. In some embodiments, the memory device further includes a second frontside metallization layer over the first frontside metallization layer. The second frontside metallization layer includes a first word line extending, along a second direction perpendicular to the first direction, over the reference voltage line and the read bit line, and a second word line extending along the second direction over the reference voltage line and the read bit line. In some implementations, the memory device further includes a third frontside metallization layer over the second frontside metallization layer. The third frontside metallization layer includes a first bit line extending along the first direction over the first word line and the second word line, and a second bit line extending along the first direction over the first word line and the second word line. In some embodiments, the memory device further includes a fourth frontside metallization layer over the third frontside metallization layer. The fourth frontside metallization layer includes a third word line extending along the second direction over the first word line, and a fourth word line extending along the second direction over the second word line. In some instances, the plurality of nanostructures of the dummy device are interleaved by a plurality of inner spacer features and the ILD layer interfaces sidewalls of the plurality of inner spacer features.

In still another aspect, the present disclosure provides a memory structure. The memory structure includes a first pass-gate device (PG-1), a first pull-down device (PD-1), a second pull-down device (PD-2), and a second pass-gate device (PG-2) disposed over a first active region extending lengthwise along a first direction, a read pass-gate device (R-PG), a first pull-up device (PU-1), a second pull-up device (PU-2), and a dummy device disposed over a second active region extending lengthwise along the first direction, and an interlayer dielectric (ILD) layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device. A first gate structure of a first pass-gate device (PG-1) is isolated from a second gate structure of the read pass-gate device (R-PG). The first pull-down device (PD-1) and the first pull-up device (PU-1) share a third gate structure. The second pull-down device (PD-2) and the second pull-up device (PU-2) share a fourth gate structure. A fifth gate structure of the second pass-gate device (PG-2) is isolated from a sixth gate structure of the dummy device. The first pass-gate device (PG-1), the first pull-down device (PD-1), the second pull-down device (PD-2), and the second pass-gate device (PG-2) are of a first conductivity type. The read pass-gate device (R-PG), the first pull-up device (PU-1), the second pull-up device (PU-2) are of a second conductivity type different from the first conductivity type. Each of the first gate structure, the second gate structure, the third gate structure, the fourth gate structure, the fifth gate structure, and the sixth gate structure include a gate dielectric layer and a gate electrode over the gate dielectric layer. A dielectric constant of the gate dielectric layer is greater than a dielectric constant of the ILD layer.

In some embodiments, a length of the first active region is greater than a length of the second active region. In some embodiments, the first pass-gate device (PG-1), the first pull-down device (PD-1), the second pull-down device (PD-2), and the second pass-gate device (PG-2) are n-type devices, and the read pass-gate device (R-PG), the first pull-up device (PU-1), the second pull-up device (PU-2) are p-type devices. In some embodiments, the memory structure further includes a first frontside metallization layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device. The first frontside metallization layer includes a reference voltage line extending along the first direction over the first gate structure, the third gate structure, the fourth gate structure, and the fifth gate structure, and a read bit line extending along the first direction over the second gate structure, the third gate structure, the fourth gate structure, and the sixth gate structure. In some embodiments, the memory structure further includes a second frontside metallization layer over the first frontside metallization layer. The second frontside metallization layer includes a first bit line extending along the first direction over the first gate structure, the third gate structure, the fourth gate structure, and the fifth gate structure, and a second bit line extending along the first direction over the read bit line.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A memory device, comprising:
a first pass-gate device (PG-1), a first pull-down device (PD-1), a second pull-down device (PD-2), and a second pass-gate device (PG-2) disposed over a first active region extending lengthwise along a first direction; and
a read pass-gate device (R-PG), a first pull-up device (PU-1), a second pull-up device (PU-2), and a dummy device disposed over a second active region extending lengthwise along the first direction,
wherein a first gate structure of a first pass-gate device (PG-1) is isolated from a second gate structure of the read pass-gate device (R-PG),
wherein the first pull-down device (PD-1) and the first pull-up device (PU-1) share a third gate structure,
wherein the second pull-down device (PD-2) and the second pull-up device (PU-2) share a fourth gate structure,
wherein a fifth gate structure of the second pass-gate device (PG-2) is isolated from a sixth gate structure of the dummy device,
wherein a length of the first active region is greater than a length of the second active region,
wherein each of the first gate structure, the second gate structure, the third gate structure, the fourth gate structure, the fifth gate structure, and the sixth gate structure comprises a gate dielectric layer and a gate electrode over the gate dielectric layer,
wherein the gate electrode comprises a titanium-based material.

2. The memory device of claim 1, further comprising:
a first frontside metallization layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device,
wherein the first frontside metallization layer comprises:
a reference voltage line extending along the first direction over the first gate structure, the third gate structure, the fourth gate structure, and the fifth gate structure, and
a read bit line extending along the first direction over the second gate structure, the third gate structure, the fourth gate structure, and the sixth gate structure.

3. The memory device of claim 2, further comprising:
a second frontside metallization layer over the first frontside metallization layer,
wherein the second frontside metallization layer comprises:
a first bit line extending along the first direction over the first gate structure, the third gate structure, the fourth gate structure, and the fifth gate structure, and
a second bit line extending along the first direction over the read bit line.

4. The memory device of claim 3, further comprising:
a third frontside metallization layer over the second frontside metallization layer,
wherein the third frontside metallization layer comprises:
a first word line extending, along a second direction perpendicular to the first direction, over the first bit line and the second bit line, and
a second word line extending along the second direction over the first bit line and the second bit line.

5. The memory device of claim 4, further comprising:
a fourth frontside metallization layer over the third frontside metallization layer,
wherein the fourth frontside metallization layer comprises:
a third word line extending along the second direction over the first word line, and
a fourth word line extending along the second direction over the second word line.

6. The memory device of claim 4, further comprising:
a fourth frontside metallization layer over the third frontside metallization layer; and
a fifth frontside metallization layer over the fourth frontside metallization layer,
wherein the fifth frontside metallization layer comprises:
a third word line extending along the second direction over the first word line, and
a fourth word line extending along the second direction over the second word line.

7. The memory device of claim 6, wherein the fourth frontside metallization layer comprises an island vertically disposed between the first word line and the third word line.

8. The memory device of claim 1, further comprising:
an interlayer dielectric (ILD) layer over the first gate structure, the second gate structure, the third gate structure, the fourth gate structure, the fifth gate structure, and the sixth gate structure,
wherein the dummy device comprises:
a plurality of nanostructures,
the sixth gate structure wrapping around each of the plurality of nanostructures, and
a source/drain feature interfacing sidewalls of the plurality of nanostructures,
wherein the plurality of nanostructures extends between the source/drain feature and the ILD layer along the first direction.

9. The memory device of claim 1, wherein the sixth gate structure is electrically floating.

10. A memory device, comprising:
a first pass-gate device (PG-1), a first pull-down device (PD-1), a second pull-down device (PD-2), and a second pass-gate device (PG-2) disposed over a first active region extending lengthwise along a first direction;
a read pass-gate device (R-PG), a first pull-up device (PU-1), a second pull-up device (PU-2), and a dummy device disposed over a second active region extending lengthwise along the first direction; and
an interlayer dielectric (ILD) layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device,
wherein a first gate structure of a first pass-gate device (PG-1) is isolated from a second gate structure of the read pass-gate device (R-PG),
wherein the first pull-down device (PD-1) and the first pull-up device (PU-1) share a third gate structure,
wherein the second pull-down device (PD-2) and the second pull-up device (PU-2) share a fourth gate structure,
wherein a fifth gate structure of the second pass-gate device (PG-2) is isolated from a sixth gate structure of the dummy device,
wherein the dummy device comprises:
a plurality of nanostructures,
the sixth gate structure wrapping around each of the plurality of nanostructures, and
a source/drain feature interfacing sidewalls of the plurality of nanostructures,
wherein the plurality of nanostructures extends between the source/drain feature and the ILD layer along the first direction,
wherein a source/drain contact is disposed over the source/drain feature,
wherein a silicide layer is disposed between the source/drain contact and the source/drain feature,
wherein an electrical conductivity of the source/drain contact is greater than an electrical conductivity of the silicide layer.

11. The memory device of claim 10, further comprising:
a first frontside metallization layer over the ILD layer,
wherein the first frontside metallization layer comprises:
a reference voltage line extending along the first direction over the first gate structure, the third gate structure, the fourth gate structure, and the fifth gate structure, and
a read bit line extending along the first direction over the second gate structure, the third gate structure, the fourth gate structure, and the sixth gate structure.

12. The memory device of claim 11, further comprising:
a second frontside metallization layer over the first frontside metallization layer,
wherein the second frontside metallization layer comprises:
a first word line extending, along a second direction perpendicular to the first direction, over the reference voltage line and the read bit line, and
a second word line extending along the second direction over the reference voltage line and the read bit line.

13. The memory device of claim 12, further comprising:
a third frontside metallization layer over the second frontside metallization layer,
wherein the third frontside metallization layer comprises:
a first bit line extending along the first direction over the first word line and the second word line, and
a second bit line extending along the first direction over the first word line and the second word line.

14. The memory device of claim 13, further comprising:
a fourth frontside metallization layer over the third frontside metallization layer,
wherein the fourth frontside metallization layer comprises:
a third word line extending along the second direction over the first word line, and
a fourth word line extending along the second direction over the second word line.

15. The memory device of claim 10,
wherein the plurality of nanostructures of the dummy device are interleaved by a plurality of inner spacer features,
wherein the ILD layer interfaces sidewalls of the plurality of inner spacer features.

16. A memory structure, comprising:
a first pass-gate device (PG-1), a first pull-down device (PD-1), a second pull-down device (PD-2), and a second pass-gate device (PG-2) disposed over a first active region extending lengthwise along a first direction;
a read pass-gate device (R-PG), a first pull-up device (PU-1), a second pull-up device (PU-2), and a dummy device disposed over a second active region extending lengthwise along the first direction; and
an interlayer dielectric (ILD) layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device,
wherein a first gate structure of a first pass-gate device (PG-1) is isolated from a second gate structure of the read pass-gate device (R-PG),
wherein the first pull-down device (PD-1) and the first pull-up device (PU-1) share a third gate structure,
wherein the second pull-down device (PD-2) and the second pull-up device (PU-2) share a fourth gate structure,
wherein a fifth gate structure of the second pass-gate device (PG-2) is isolated from a sixth gate structure of the dummy device,
wherein the first pass-gate device (PG-1), the first pull-down device (PD-1), the second pull-down device (PD-2), and the second pass-gate device (PG-2) are of a first conductivity type,
wherein the read pass-gate device (R-PG), the first pull-up device (PU-1), the second pull-up device (PU-2) are of a second conductivity type different from the first conductivity type,
wherein each of the first gate structure, the second gate structure, the third gate structure, the fourth gate structure, the fifth gate structure, and the sixth gate structure comprise a gate dielectric layer and a gate electrode over the gate dielectric layer,
wherein a dielectric constant of the gate dielectric layer is greater than a dielectric constant of the ILD layer.

17. The memory structure of claim 16, wherein a length of the first active region is greater than a length of the second active region.

18. The memory structure of claim 16,
wherein the first pass-gate device (PG-1), the first pull-down device (PD-1), the second pull-down device (PD-2), and the second pass-gate device (PG-2) are n-type devices,
wherein the read pass-gate device (R-PG), the first pull-up device (PU-1), the second pull-up device (PU-2) are p-type devices.

19. The memory structure of claim 16, further comprising:
a first frontside metallization layer over the first pass-gate device (PG-1), the first pull-down device (PD-1), the second pull-down device (PD-2), the second pass-gate device (PG-2), the read pass-gate device (R-PG), the first pull-up device (PU-1), the second pull-up device (PU-2), and the dummy device,
wherein the first frontside metallization layer comprises:
a reference voltage line extending along the first direction over the first gate structure, the third gate structure, the fourth gate structure, and the fifth gate structure, and
a read bit line extending along the first direction over the second gate structure, the third gate structure, the fourth gate structure, and the sixth gate structure.

20. The memory structure of claim 19, further comprising:
a second frontside metallization layer over the first frontside metallization layer,
wherein the second frontside metallization layer comprises:
a first bit line extending along the first direction over the first gate structure, the third gate structure, the fourth gate structure, and the fifth gate structure, and
a second bit line extending along the first direction over the read bit line.
